(19) United States
(12) Patent Application Publication
(10) Pub. No.: US 2025/0257239 A1
(43) Pub. Date: Aug. 14, 2025

(54) POLYSILOXANE COMPOSITIONS FOR OPTOELECTRONIC DEVICE APPLICATIONS INVOLVING MOISTURE SENSITIVE LAYERS

(71) Applicant: Honeywell International Inc., Charlotte, NC (US)

(72) Inventors: Hongmin Huang, Cupertino, CA (US); Songyuan Xie, E. Palo Alto, CA (US); Amanuel H. Gebrebrhan, San Jose, CA (US); Desaraju Varaprasad, Dublin, CA (US); Tiffany Nguyen, Charlotte, NC (US); Tram Le, Charlotte, NC (US); Tianyu Liu, Charlotte, NC (US)

(21) Appl. No.: 19/045,352

(22) Filed: Feb. 4, 2025

Related U.S. Application Data
(60) Provisional application No. 63/551,157, filed on Feb. 8, 2024.

(51) Int. Cl. C09D 183/06; C09D 7/80; H01L 21/02

(52) U.S. Cl. CPC C09D 183/06; C09D 7/80; H01L 21/02118; H01L 21/02211; H01L 21/02216; H01L 21/02359

(57) ABSTRACT

A method of forming a composition for planarizing the surface of a semiconductor device by combining silicon-containing compounds selected from one or more of silanes, polysiloxanes, poly(silsesquioxanes) and combinations of the foregoing, and controlling and/or reducing the SiOH functional group content of the polysiloxanes such that condensation of SiOH functional groups of the polysiloxanes and resulting moisture evolution is minimized on final application and cure onto a semiconductor device having moisture-sensitive layers.

### CROSS-REFERENCE TO RELATED APPLICATIONS

This application claims the benefit under 35 U.S.C. § 119(e) of U.S. Provisional Application No. 63/551,157 entitled “POLYSILOXANE COMPOSITIONS FOR OPTOELECTRONIC DEVICE APPLICATIONS INVOLVING MOISTURE SENSITIVE LAYERS”, filed on Feb. 8, 2024, the entire disclosure of which is incorporated by reference in its entirety.

### FIELD

The present disclosure relates generally to polysiloxane coating compositions for semiconductor devices, such as optoelectronic devices, and more specifically to methods for forming and applying polysiloxane compositions for planarizing or otherwise modifying the surfaces of a semiconductor device.

### BACKGROUND

Thin film transistors are a type of semiconductor device made using thin films of semiconductor materials and are used to control the individual pixels in flat panel displays, particularly in Liquid Crystal Displays (LCDs), Organic Light Emitting Diodes (OLEDs), and micro LEDs. Optoelectronic devices that employ thin film transistors (TFT) often use advanced semiconductor coating materials such as amorphous silicon TFT, oxide TFT, such as IGZO (Indium Gallium Zinc Oxide), low temperature polycrystalline silicon (LTPS) TFT, and microcrystalline TFT.

Solution-processed polysiloxanes are used as dielectric layers in these applications as they are also cost effective in addition to offering certain benefits over the conventional dielectric materials. These polysiloxane layers are typically deposited from solutions of polymeric siloxanes, which are thermally cured to form stable thin film dielectric layers. During the thermal curing process of polysiloxanes water is released as a byproduct of condensation reaction, which may be detrimental to layers such as IGZO that are moisture sensitive.

What is needed are coatings based on polymeric siloxanes that are an improvement over the foregoing.

### SUMMARY

The present disclosure is based on the finding that providing coating compositions including polysiloxanes having a reduced silanol functional group content helps to prevent potential damage to moisture sensitive layers in semiconductor devices during application and curing. The approach presented herein involves the synthesis of polysiloxanes having a controlled silanol functional group content and/or polysiloxane treatment steps to reduce the silanol functional group content of the polysiloxanes in coating formulations before the coatings are applied and cured onto a semiconductor device having moisture sensitive layers.

In one form thereof, the present disclosure provides a method of forming a coating composition for planarizing the surface of a semiconductor device. The method includes combining silicon-containing compounds selected from one or more of silanes, polysiloxanes, poly(silsesquioxanes), and combinations of the foregoing to form a composition; and pre-condensing the composition to reduce the first, initial silanol group (SiOH) to a second, reduced silanol group (SiOH) content. The silicon-containing compounds have a first, initial silanol group (SiOH) content following combining.

The present disclosure further provides a method of planarizing a surface of a semiconductor device. The method includes applying, to a surface of a semiconductor device, a composition comprising the reaction product of one or more of silanes, polysiloxanes, poly(silsesquioxanes), and combinations of the foregoing; and curing the composition to provide a second, reduced silanol group (SiOH) content with a silanol group (SiOH) loss of less than 0.3. The silicon-containing compounds have a first, initial silanol group (SiOH) content following combining.

The present disclosure provides a composition for planarizing the surface of a semiconductor device. The composition includes the reaction product of one or more of silicone monomers, polysiloxanes, poly(silsesquioxanes), and combinations of the foregoing. The reaction product has a first, initial silanol group (SiOH) content and is capable, upon application to a surface of a semiconductor device and curing, of providing a second, reduced silanol group (SiOH) with a silanol group (SiOH) loss of less than 0.3.

### BRIEF DESCRIPTION OF THE DRAWINGS

FIG. 1 is a schematic of an exemplary thin film transistor.

FIG. 2 is an FTIR spectrum showing the silanol (SiOH) peak area at 839 cm⁻¹ to 980 cm⁻¹ and two absorbance curves corresponding to a device before and after curing; and

FIG. 3 is a graph of the moisture content before and following curing as measured according to the present disclosure.

### DETAILED DESCRIPTION

### I. Definitions

As used herein, the singular forms “a”, “an” and “the” include plural unless the context clearly dictates otherwise. Moreover, when an amount, concentration, or other value or parameter is given as either a range, preferred range, or a list of upper preferable values and lower preferable values, this is to be understood as specifically disclosing all ranges formed from any pair of any upper range limit or preferred value and any lower range limit or preferred value, regardless of whether ranges are separately disclosed. Where a range of numerical values is recited herein, unless otherwise stated, the range is intended to include the endpoints thereof, and all integers and fractions within the range. It is not intended that the scope of the disclosure be limited to the specific values recited when defining a range.

As used herein, the phrase “within any range encompassing any two of these values as endpoints” literally means that any range may be selected from any two of the values listed prior to such phrase regardless of whether the values are in the lower part of the listing or in the higher part of the listing. For example, a pair of values may be selected from two lower values, two higher values, or a lower value and a higher value.

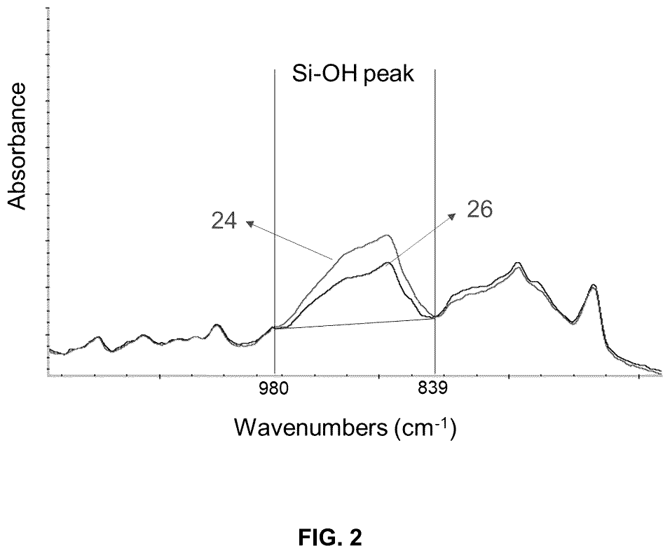

As used herein, the term “silanol loss”, “silanol group (SiOH) group loss”, or “SiOH loss” refers to the amount of silanol (SiOH) functional groups in the coating compositions of the present disclosure that are condensed or lost during the curing of the coating compositions onto a semiconductor substrate. With reference to FIG. 2 showing silanol (SiOH) peaks 24 and 26 before and after curing, the amount of silanol group (SiOH) loss is determined by the difference in the normalized areas under first and second peaks 24 and 26, calculated by the equation below:

$${A}_{NS} = 1000 \times As / FT ( Å )$$

wherein:
   A_{NS} is the normalized SiOH peak area;
   As is the SiOH peak area from 839 cm⁻¹ to 980 cm⁻¹ measured on FTIR absorbance spectra; and
   FT is the thickness of the film in Angstroms (Å);
      wherein silanol (SiOH) loss is the difference in A_{NS} before and after curing, as follows:

$$Silanol group ( SiOH ) loss = {A}_{NS} ( Before curing ) - {A}_{NS} ( After curing )$$

and wherein:
peak 24, i.e., the first peak, is measured following subjecting the coating composition to 2-step proximity baking of a coated silicon wafer using a hotplate at 80° C. for 1 min and then at 160° C. for 2 min with a 1 mm gap between the wafer and the hotplate; and
peak 26, i.e., the second peak, is measured following final cure of the coating composition over a semiconductor surface at 300° C. for 60 minutes under a nitrogen atmosphere in a furnace.

As used herein, the term “moisture sensitive layer” refers to a layer in a semiconductor device or package which is prone damage by exposure to moisture, for example, an amorphous IGZO (Indium Gallium Zinc Oxide) layer, a metal gate layer and/or a dielectric layer.

As used herein, the term “water scavenger” refers to a chemical substance (e.g., compound, oligomer or polymer) or chemical composition which can readily capture water or moisture by physical absorption or chemical reactions to prevent and/or mitigate damage of a moisture sensitive layer by exposure to moisture.

As used herein, the term “aryl/alkyl ratio” refers to the molar ratio of the total moles of aryl groups divided by the total moles of alkyl groups, based on the total mol % of all alkyl and aryl groups in all of the silicon-containing compounds within the coating composition.

As used herein, the term “pre-condensed” and/or the step “pre-condensing” refer to any one or more of the use of a catalyst, the application of heat, and/or exposure to electromagnetic radiation to promote hydrolysis and/or condensation of the silicon containing compounds prior to the step of final curing of the coating composition onto a substrate.

### II. Introduction

The present disclosure is based on the finding that providing coating compositions including polysiloxanes having a reduced silanol functional group content helps to prevent damage to moisture sensitive layers in semiconductor devices during application and curing. The approach presented herein involves the synthesis of polysiloxanes having a controlled silanol functional group content and/or polysiloxane treatment steps to reduce the silanol functional group content of the polysiloxanes in coating formulations before the coatings are applied and cured onto a semiconductor device having moisture sensitive layers. The coating compositions which are applied and cured onto a semiconductor device yet also retain sufficient silanol groups to compete condensation of the silanol groups on the surface of the semiconductor device.

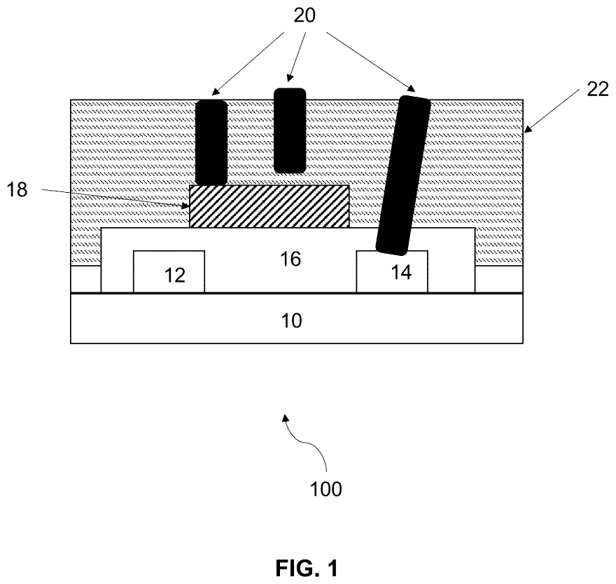

FIG. 1 is a schematic of an exemplary semiconductor device shown as a thin film transistor 100 including a glass substrate 10 with two gates 12 and 14. A gate insulating layer 16 is deposited on top of the gates 12 and 14. A moisture sensitive layer, for example, amorphous IGZO (Indium Gallium Zinc Oxide) 18, is disposed over the gate insulating layer and contacts sources and drains 20. Other moisture sensitive layers may include metal gate layers and/or dielectric layers. The entire package or stack-up is coated and surrounded by passivation layer 22 which passivates and/or planarizes the device surface.

The crosslinking and/or continued polymerization of the polysiloxanes of the coating composition which forms passivation layer 22 releases water due to condensation of the silanol groups of the polysiloxanes upon final cure, as shown in the generalized reaction below. After the initial silicon-containing compounds are exposed to water, a hydrolysis reaction may convert the hydrolyzable groups (—OR) into silanol groups (Si—OH). The silanol groups may then be condensed to form the Si—O—Si linkages. Coating compositions according to the present disclosure are subjected to a pre-condensing step, discussed further below, which promotes a controlled degree of hydrolysis and condensation to remove SiOH groups prior to application of the coating compositions to substrates followed by curing.

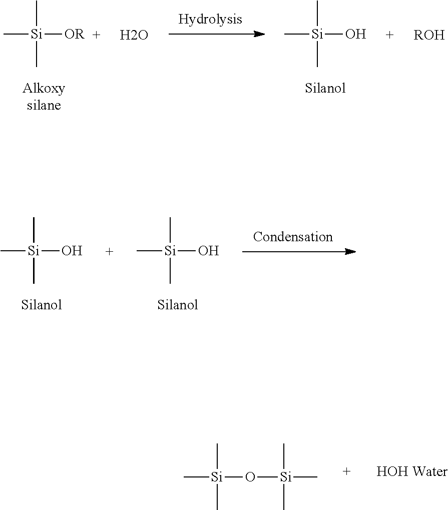

Alkoxy silanes, such as silane monomers, may include multiple hydrolyzable —OR groups on each Si atom that may be hydrolyzed during hydrolysis and then further condensed during curing. Referring to Table A below, monofunctional, difunctional, trifunctional, or tetrafunctional silanol units may be condensed to form polysiloxanes. As discussed below, the silanol units may be in the form of silane or alkoxy silane monomers, polysiloxanes and/or poly(silsesquioxanes), or combinations thereof which are combined to formulate the coating composition.

Problematically, moisture sensitive layers or semiconductor components such as IGZO may be damaged during curing. As discussed below, to provide coating compositions which demonstrate minimized moisture loss upon application and cure to a semiconductor substrate, the present disclosure provides polysiloxanes that have been synthesized to have a controlled silanol functional group content and/or have been subjected to treatment steps to reduce the silanol functional group content of the polysiloxanes before they are applied and cured onto a substrate.

### III. Silicon-Containing Compounds

The siloxanes or polysiloxanes of the present coating compositions may be formed from silicon-containing monomers, polysiloxanes, and/or poly(silsesquioxanes) which, as discussed below, are subjected to limited or controlled hydrolysis and/or condensation reactions before being formulated into coating compositions which are applied and cured onto semiconductor substrates.

### A. Monomers

The silicon-based components may include, or be formed from, silicon monomers or alkoxy silanes of the formula (I):

RₓSi(OR′)₄₋ₓ (I)
wherein:
   R is one or more moieties chosen independently from linear, branched, or cyclic alkyl and aryl;
   R′ is methyl, ethyl, propyl or alkyl; and
   x is at least 0 and less than 4, including any of 0, 1, 2 and 3.

In formula (I), R is C₆ aryl or a linear or branched alkyl having from as few as 1, 2, 3, or as many as 4, 5, 6, or more carbon atoms, or a number of carbon atoms within any range defined between any two of the foregoing values, such as 1, 2, 3, 4, 5, or 6 carbon atoms. For example, R may selected from methyl, ethyl, propyl, and phenyl.

Each silicone monomer may be described according to the degree of oxygen substitution, or functionality, on the central silicon, as shown in Table A.

TABLE A
Silicone Monomer Types

| Structural formula | Functionality | Symbol |
|---|---|---|
| R₃Si—O— | Monofunctional | M |
| 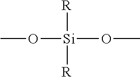 | Difunctional | D |
| 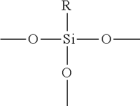 | Trifunctional | T |
| 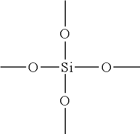 | Tetrafunctional | Q |

The organoalkoxysilane may be selected from the group consisting of: methyltrimethoxysilane, methyltriethoxysilane, dimethyldiethoxysilane, dimethyldimethoxysilane, trimethylmethoxysilane, trimethylethoxysilane, phenyltrimethoxysilane, phenyl triethoxysilane, and combinations of the foregoing.

The organoalkoxysilane may be a functionalized siloxane, such as 3-aminopropyltriethoxysilane, (3-glycidoxypropyl)trimethoxysilane, and allyltrimethoxysilane.

The coating composition may comprise a wt. % of silicone monomers from about 0.01 wt. %, about 0.1 wt. %, or about 1 wt. % to about 30 wt. %, about 50 wt. %, or about 90 wt. %, or any range using any two of the foregoing values as endpoints, such as from about 0.01 wt. % to about 90 wt. %, about 0.1 wt. % to about 50 wt. %, or about 1 wt. % to about 30 wt. %, based on the total weight of the coating composition.

i. Difunctional Silicone Monomers

The coating composition may comprise difunctional silicone monomers. The difunctional silicone monomer may be represented by formula (II):

R₂Si(OR′)₂ (II)
wherein:
   R is one or more moieties chosen independently from linear, branched, or cyclic alkyl and aryl; and
   R′ is methyl, ethyl, propyl or alkyl.

Suitable difunctional siloxane monomers (D units) used to produce the polysiloxane polymer may include diethoxydiphenyl silane, methylphenyldiethoxy silane, diethoxydimethyl silane, dimethyldimethoxy silane, diphenyldimethoxy silane, diphenyldiethoxy silane, methylphenyldimethoxy silane, dimethyldiethoxy silane, diphenyldiethoxy silane, and methylphenyldiethoxy silane.

The coating composition may comprise a wt. % of difunctional silicone monomers from about 0.001 wt. %, about 0.01 wt. %, or about 0.05 wt. % to about 5 wt. % about 10 wt. %, or about 30 wt. %, or any range using any two of the foregoing values as endpoints, such as from about 0.001 wt. % to about 30 wt. %, about 0.01 wt. % to about 10 wt. %, or about 0.05 wt. % to about 5 wt. %, based on the total weight of the coating composition.

i. Bipodal Silicone Monomers

The coating composition may comprise bipodal silicone monomers. Bipodal silicone monomers describe silicone monomers that have two functional groups on either side of the central R group. Each functional group may be reactive to act as bonding sites to other components.

The bipodal silicone monomer may be represented by formula (III):

(OR¹)₃Si—R²—Si(OR³)₃ (III)
wherein:
   R¹ is methyl, ethyl, propyl, or alkyl;
   R² is an organic group comprising aliphatic and/or aromatic hydrocarbons; and
   R³ is methyl, ethyl, propyl, or alkyl.

Suitable bipodal siloxane monomers used in the coating composition may include bis(trimethoxy silyl methane), bis(triethoxy silyl methane), bis(trimethoxy silyl ethane), bis(triethoxy silyl ethane), bis(trimethoxysilyl)benzene, bis(triethoxysilyl)benzene, bis(triethoxysily)oxtane, bis(trimethoxysily)oxtane bis(trimethoxysilyl)bi-benzene, bis(triethoxysilyl)bi-benzene, bis(trimethoxysilylpropyl) amine, bis(triethoxysilylpropyl) amine, and glycidyloxypropyltrimethoxysilane, Bis[3-(triethoxysilyl)propyl]-disulfide.

The coating composition may comprise a wt. % of bipodal silicone monomers from about 0.001 wt. %, about 0.01 wt. %, or about 0.1 wt. % to about 1 wt. %, about 5 wt. %, or about 10 wt. %, or any range using any two of the foregoing values as endpoints, such as from about 0.001 wt. % to 10 wt. %, about 0.01 to about 5 wt. %, or about 0.1 wt. % to about 1 wt. %, based on the total weight of the coating composition.

### B. Polysiloxanes

The silicon-based components may include polymerized siloxane or polysiloxane. The coating composition may be initially formulated with one or more polysiloxanes and/or one or more polysiloxanes may be present in the coating composition resulting from condensation reactions of the monomers in section IA. Further, monomers of IA may form a polysiloxane and then react with the polysilsesquioxanes of section IC (below).

A siloxane is a chemical compound having branched or unbranched backbones consisting of alternating silicon and oxygen atoms —Si—O—Si—O— with side chains R attached to the silicon atoms (R₁R₂SiO), where R is a hydrogen atom or a hydrocarbon group. Polysiloxanes may include oligomeric and/or polymeric siloxane units, optionally having organic side chains, which may be represented by formula (IV) shown below, where “n” indicates a repeat unit greater than 1:

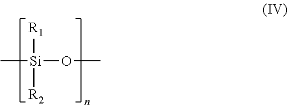

wherein n is at least 3 and less than 10,000.

In addition to hydrogen, R₁ and R₂ of polysiloxane are independently selected from the group consisting of an alkyl, an alkenyl, a cycloalkyl, an alkylamino, aryl, aralkyl, or alkylsilyl.

Thus, R₁ and R₂ may be methyl, ethyl, propyl, butyl, octyl, decyl, vinyl, allyl, butenyl, octenyl, decenyl, tetradecyl, hexadecyl, eicosyl, tetracosyl, cyclohexyl, methylcyclohexyl, methylamino, ethylamino, phenyl, tolyl, xylyl, naphthyl, benzyl, methylsilyl, ethylsilyl, propylsilyl, butylsilyl, octylsilyl, or decylsilyl.

The alkyl, alkenyl, cycloalkyl, aryl, alkyl amino, aralkyl and alkylsilyl groups may each optionally be substituted by one or more substituents which contain heteroatoms, such as halides, like chlorine, bromine and iodine; alkoxy groups, like ethoxy, and also aryl groups, such as acetyl and propionyl. Organic side groups can be used to link two or more of these —Si—O— backbones together. By varying the —Si—O— chain lengths, side groups, and crosslinking, polysiloxanes can vary in consistency from liquid to gel to rubber to hard plastic.

Representative examples of polysiloxane are [SiO(CH₃)₂]ₙ (polydimethylsiloxane, PDMS) and [SiO(C₆H₅)₂]ₙ (polydiphenylsiloxane). For example, the silicon-based coating composition may include polydimethylsiloxane having the chemical structure shown below.

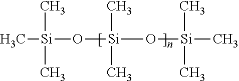

A weight average molecular weight of polysiloxanes useful for forming polysiloxanes of the coating composition may be from 300 Da, 800 Da, 1000 Da, 5000 Da, or 10,000 Da to 30,000 Da, 40,000 Da, 50,000 DA, 100,000 Da, or 200,000 Da, or any range using any two of the foregoing values as endpoints, such as 300 Da to 200,000 Da, 800 Da to 100,000 Da, 1000 Da to 50,000 Da, 5000 Da to 40,000 Da, or 10,000 Da to 30,000 Da, as determined by gel permeation chromatography (GPC) with polystyrene standards.

### C. Polysilsesquioxanes

The silicon-based components may include polymerized silsesquioxanes.

Silsesquioxanes are cage-like molecules containing silicon and oxygen atoms. Their polymerization process links the cage-like units to form a larger, three-dimensional polymer network. The silsesquioxane polymer may include poly(methylsilsesquioxane) monomers with the formula [RSiO_{3/2}]ₙ, wherein R is a hydrogen, an alkyl group, an aryl group, or an alkoxyl group. For example, the polysilsesquioxane monomers can include poly(methylsilsesquioxane) blocks, poly(phenylsilsesquioxane) blocks, poly(methylphenylsilsesquioxane) or any combinations thereof.

Suitable commercially available polysilsesquioxane resins include GR650F resin, GR100F resin, GR150F resin, and GT950F resin obtainable from Techneglas of Perrysburg, Ohio.

The GR150F and GR100F resins comprise, consist essentially of, or consist of poly(phenylsilsesquioxane) blocks and poly(methylsilsesquioxane) blocks.

The GR950F resin comprises, consists essentially of, or consists of poly(phenylsilsesquioxane) blocks.

The GR650F resin comprises, consists essentially of, or consists of poly(methylsilsesquioxane) blocks.

A weight average molecular weight of the silsesquioxanes useful for forming polysiloxanes of the coating composition may be from 300 Da, 800 Da, 1000 Da, 5000 Da, or 10,000 Da to 30,000 Da, 40,000 Da, 50,000 DA, 100,000 Da, or 200,000 Da, or any range using any two of the foregoing values as endpoints, such as 300 Da to 200,000 Da, 800 Da to 100,000 Da, 1000 Da to 50,000 Da, 5000 Da to 40,000 Da, or 10,000 Da to 30,000 Da, as determined by gel permeation chromatography (GPC) with polystyrene standards.

The monomers, polysiloxanes, and/or polysilsequioxanes may together comprise as little as 1 wt. %, 5 wt. %, 10 wt. %, 15 wt. %, 20 wt. %, 25 wt. %, 30 wt. %, 35 wt. %, 40 wt. %, 45 wt. %, 50 wt. %, 60 wt. %, 70 wt. %, 75 wt. %, 80 wt. %, 85 wt. %, 90 wt. %, 95 wt. %, 99 wt. %, or within any range encompassed by any two of the foregoing values as endpoints, of the coating composition based on the total weight of the composition. For example, the monomers, polysiloxanes, and/or polysilsequioxanes may comprise from 1 wt. % to 99 wt. %, 25 wt. % to 99 wt. %, from 40 wt. % to 80 wt. %, or from 50 wt. % to 70 wt. % of the coating composition, based on the total weight of the composition.

### D. Combination of Silicon-Containing Compounds

The polysiloxane coating composition of present disclosure may comprise a combination or mixture of silicone monomers, polysiloxanes, and polysilsesquioxanes. Each silicon-containing compound may be polymerized together.

The coating composition may include only polysilsesquioxanes; only siloxane monomers; only polysiloxanes; a combination of polysilsesquioxanes and siloxane monomers; a combination of polysilsesquioxanes and polysiloxanes; a combination of siloxane monomers and polysiloxanes; and a combination of polysilsesquioxanes, siloxane monomers, and polysiloxanes.

### E. Aryl/Alkyl Ratio

The aryl/alkyl ratio may significantly influence mechanical properties of the composition. In a composition with a higher aryl/alkyl ratio, the organic content of the composition may be higher as well, making the coating softer. As aryl groups are also bulkier, the increased aryl/alkyl ratio may also reduce reactivity of silanol groups due to the high steric hindrance of phenyl groups, making the coating more flexible.

Each silicon-containing compound may have a molar ratio of aryl groups to alkyl groups based on the mol % of silicon-containing compound within the polysiloxane coating composition. A high aryl/alkyl ratio may help produce films with a higher crack-free thickness limit.

The silicon-containing compound of the coating composition may have an aryl/alkyl ratio from about 0.9 to about 10, wherein the molar ratio is based on the total moles of aryl groups divided by the total moles of alkyl groups, based on the total mol % of all alkyl and aryl groups in all of the silicon-containing compounds within the coating composition.

### IV. Catalysts

The catalyst for the condensation reaction may be selected from an acid catalyst or a base catalyst, though the catalyst is optional, as the condensation reaction may occur with elevated heat in the absence of a catalyst.

Acid catalysts may provide a longer pot life for the mixture. Exemplary acid catalysts include inorganic and organic acids such as hydrochloric acid, phosphorous acid, phosphoric acid, phytic acid, nitric acid, acetic acid, oxalic acid, malic acid, maleic acid, citric acid, formic acid, and benzoic acid.

Exemplary base catalysts include organic and inorganic bases such as such as sodium hydroxide, ammonium hydroxide, ethanolamine, or dimethylaminoethanol.

The catalyst can include, for example, tetramethylammonium acetate (TMAA), tetramethylammonium hydroxide (TMAH), tetrabutylammonium acetate (TBAA), tetrabutylammonium hydroxide (TBAH), tetraethylammonium acetate (TEAA), tetraethylammonium hydroxide (TEAH), cetyltrimethylammonium acetate (CTAA), cetyltrimethylammonium hydroxide (CTAH), cetyltrimethylammonium nitrate (CTAN), tetrabutylammonium nitrate (TBAN), tetraethylammonium nitrate, (TEAN), tetramethylammonium nitrate (TMAN), triphenylamine, trioctylamine, tridodecylamine, triethanolamine, tetramethylphosphonium acetate, tetramethylphosphonium hydroxide, triphenylphosphine, trimethylphosphine, trioctylphosphine, aminopropyltriethoxysilane, aminopropyltriethoxysilane triflate, and any combinations thereof.

The catalyst comprises as little as 0.001 wt. %, 0.005 wt. %, 0.01 wt. %, 0.05 wt. %, 0.1 wt. %, 0.2 wt. %, 0.3 wt. %, 0.5 wt. %, as great as 1 wt. %, 2 wt. %, 3 wt. %, 5 wt. %, of the total composition weight on a wet basis, or within any range defined between any two of the foregoing values, such as 0.05 wt. % to 5 wt. %, 0.1 wt. % to 3 wt. %, or 0.3 wt. % to 3 wt. %.

### V. Solvents and Additives

The silicon-based coating compositions of the present disclosure may additionally include one or more solvents. Exemplary solvents include suitable pure organic molecules or mixtures thereof that are volatilized at a desired temperature and/or easily solvate the components discussed herein. The solvents may also comprise suitable pure polar and non-polar compounds or mixtures thereof. As used herein, the term “pure” means a component that has a constant composition. For example, pure water is composed solely of H₂O. As used herein, the term “mixture” means a component that is not pure, including salt water. As used herein, the term “polar” means that characteristic of a molecule or compound that creates an unequal charge, partial charge or spontaneous charge distribution at one point of or along the molecule or compound. As used herein, the term “non-polar” means that characteristic of a molecule or compound that creates an equal charge, partial charge or spontaneous charge distribution at one point of or along the molecule or compound.

Exemplary solvents include solvents that can, alone or in combination, modify the viscosity, intermolecular forces and surface energy of the solution in order to, in some cases, improve the gap-filling and planarization properties of the composition. It should be understood, however, that suitable solvents may also include solvents that influence the profile of the composition in other ways, such as by influencing the crosslinking efficiency, influencing the thermal stability, influencing the viscosity, and/or influencing the adhesion of the resulting layer or film to other layers, substrates or surfaces.

Although one skilled in the art will appreciate that a wide variety of solvents may be incorporated into the current disclosure, suitable solvents for the present disclosure are those that contain no water and no reactive groups such as hydroxyl or amine groups. These solvents include, but not limited to, for example, aromatic hydrocarbons; aliphatic hydrocarbons, such as, hexane, heptane, benzene, toluene, branched-chain alkanes (isoparaffins); halogenated hydrocarbons; esters, such as methyl acetate, n-butyl acetate, tert-butyl acetate, isobutyl acetate, sec-butyl acetate, ethyl acetate, amyl acetate, pentyl acetate, 2-methyl butyl acetate, isoamyl acetate, n-propyl acetate, isopropyl acetate, ethylhexyl acetate; ketones, such as acetone or methyl ethyl ketone; ethers, such as tetrahydrofuran, dibutyl ether; and mono- and polyalkylene glycol dialkyl ethers (glymes) or mixtures of these solvents may be used.

The silicon based coating compositions of the current disclosure may further include one or more additives including, but not limited to, curing agents, water scavengers, matting agents, pigments, fillers, flow control agents, dry flow additives, anti-cratering agents, surfactants, texturing agents, light stabilizers, matting agents, photosensitizers, wetting agents, anti-oxidants, plasticizers, opacifiers, stabilizers, degassing agents, corrosion inhibitors, ceramic microspheres, slip agents, dispersing agents, and surface altering additives.

It has been found that a surfactant can further reduce striations, which may be particularly useful when the composition is spin-coated onto larger diameter semiconductor device wafers or display substrates. The surfactant can be a polyether-modified polydimethylsiloxane surfactant, such a BYK®-306 or BYK®-307 available from BYK-Chemie, Wesel, Germany.

The concentration of the surfactant in the composition can be as low as 0.001 wt. %, 0.01 wt. %, 0.1 wt. %, 0.4 wt. %, 0.6 wt. %, or 0.8 wt. %, or as high as 1 wt. %, 5 wt. %, 10 wt. %, 15 wt. %, or 20 wt. % of the total weight of the composition, or within any range defined by any two of the preceding values, for example, in some embodiments, the concentration of the surfactant in the composition can range from 0.01 wt. % to 20 wt. %, 0.1 wt. % to 15 wt. %, 0.4 wt. % to 10 wt. %, 0.6 wt. % to 5 wt. %, or 0.8 wt. % to 1 wt. % of the total weight of the composition.

The composition can further include a cross-linker. Cross-linkers form bonds in the polysiloxane resin. Without wishing to be bound by any theory, it is believed that the bonds provided by the cross-linker provide additional structure and strength to the planarizing, providing additional crack resistance. The cross-linker can include bis-(trimethoxysilylpropyl) amine, 1,3 bis(triethoxysilyl) benzene, 1,4 bis(triethoxysilyl) benzene, 2,6-bis(triethoxysilyl)-naphthalene, 9,10-bis(triethoxysilyl)-anthracene, 1,6-bis(trimethoxysilyl)-pyrene, bis(triethoxysilyl) methane, 1,2-bis(triethoxysily) ethane, or 1-(triethoxysilyl)-2-(diethoxymethylsilyl) ethane, or any combination thereof.

### VI. Water Scavengers

The coating compositions of the present disclosure may additionally include one or more optional water scavengers. Exemplary water scavengers are silanes with methoxy groups, ethoxy groups, or a combination thereof, for example vinyl functional silanes, such as vinyltriethoxysilanes, including PC6110 and PC6120 available from SiSiB Silicones, or other alkoxysilanes such as hexadecyltrimethoxysilane (SIH5925.0), vinylmethyldimethoxysilane (SIV9086.0), or methyltriacetoxysilane (SIM6519.0) each available from Gelest.

### VII. Pre-Condensing

Once the silicon-containing compounds, solvents, additives, and water scavengers are combined to form a coating composition, the coating composition may be subjected to a pre-condensing step to promote a controlled extent of hydrolysis and subsequent condensation of the SiOH groups into Si—O—Si linkages before the coating compositions are applied onto a substrate and cured.

Pre-condensing the silicon-containing compounds, solvents, additives, and water scavengers may maximize Si—OH group loss prior to final curing of the coating composition onto a substrate. Si—OH group loss during pre-condensing removes moisture from the composition. By maximizing the Si—OH group loss at the pre-condensing stage, the amount of moisture evolution observed during final cure of the coating onto a substrate may be minimized, as discussed further below. The percentage of SiOH groups removed may be determined using the method described in section I and may be calculated by the difference in the SiOH loss from the curing between the compositions after pre-condensing and the amount of SiOH groups before pre-condensing, divided by the SiOH loss before pre-condensing.

Pre-condensing may remove at least 30%, at least 35%, at least 40%, at least 45%, at least 50%, at least 55%, at least 60%, at least 65%, at least 70%, at least 75%, at least 80%, at least 85%, at least 90%, or at least 95% of Si—OH groups, based on the total number of Si—OH groups in the coating composition before pre-condensing. Stated differently, the amount of SiOH groups remaining in the coating composition after pre-condensing and prior to final cure may be less than 70%, less than 60%, less than 50%, less than 40%, less than 30%, less than 20%, less than 10%, or less than 5% based on the total number of Si—OH groups in the coating composition before pre-condensing.

The pre-condensing step typically involves exposing the silicon-containing compound(s) to a heat treatment. This initial pre-condensing has been found to reduce the number of silanol (SiOH) groups in the polymer by consuming them via further polymerization.

The pre-condensing may be performed at a temperature as low as 40° C., 50° C., 60° C., 70° C., 80° C., 90° C., 100° C., 110° C., 120° C., or as high as 130° C., 140° C., 150° C., 160° C., 170° C., 180° C., or within any range encompassed by any two of the foregoing values as endpoints. For example, the baking step may be done at a temperature of from 80° C. to 160° C., or from 100° C. to 150° C.

The pre-condensing step may be carried out for 1 minute, 2 minutes, 3 minutes, 4 minutes, 5 minutes, 6 minutes, 7 minutes, 8 minutes, 9 minutes, or 10 minutes, or within any range encompassed by any two of the foregoing values as endpoints. For example, the pre-condensing step may take from 1 minute to 10 minutes, or from 3 minutes to 8 minutes.

After the polysiloxanes are pre-condensed, a weight average molecular weight of the polysiloxanes of the coating composition may be from 300 Da, 800 Da, 1000 Da, 5000 Da, or 10,000 Da to 30,000 Da, 40,000 Da, 50,000 DA, 100,000 Da, or 200,000 Da, or any range using any two of the foregoing values as endpoints, such as 300 Da to 200,000 Da, 800 Da to 100,000 Da, 1000 Da to 50,000 Da, 5000 Da to 40,000 Da, or 10,000 Da to 30,000 Da, as determined by gel permeation chromatography (GPC) with polystyrene standards.

### VIII. Coating and Curing

A method for making a coating composition in accordance with embodiments of this disclosure can include providing at least one polysiloxane resin as described above and dissolving the polysiloxane resin in the one or more solvents to form a resin solution. Dissolving the polysiloxane resin can be encouraged by mixing the polysiloxane resin into the one or more solvents for one to four hours. A catalyst as described above can be added to the resin solution. In some embodiments, a surfactant as described above can also be added to the resin solution. The resin solution can be stirred for several more hours, for example, three hours to form the composition. The composition may then be filtered through a 0.1 micron filter.

### A. Coating

The coating compositions of the present disclosure may be applied to a substrate by dipping, spraying, brushing, painting, wiping, immersion, or spin-coating techniques. These procedures will typically provide polymer coatings of thicknesses on the order of 0.01 micron (μ, or micrometer am) or even thinner, to up to about 75 micron per coat for the cured polymers. If a thicker coating is desired, multiple coating layers may be provided. The clear coat formulations as provided herein result in a coating transparent and therefore do not affect the optical appearance of the substrate. Due to the small coat thickness, only a very small amount of material is required, which is advantageous both in terms of cost and also ecologically, and the weight change of the substrate to be coated is nearly unnoticeable. The coat thickness of the silicon-based coating as provided herein following evaporation of the solvent and curing is in the range from about 0.1 to about 50 microns, preferably from about 0.5 to about 40 microns, particularly preferably from about 1 to about 25 microns.

For spin-coating techniques, a coating composition may be applied to the substrate and then the substrate is rapidly spun to spread the composition across its surface. After one coat has been applied, the substrate may be heated to drive off substantially all of the solvent and form an uncured film. Once the solvent is substantially driven off, a second coating of the composition may be applied on the uncured film, and it may be heated again to drive off solvent. The coating and heating processes can be repeated until a desired thickness of the coating is realized.

Other suitable coating techniques include slot die coating, dip coating, and spray coating.

Surfaces, substrates and substrate layers suitable for coating compositions provided herein may comprise any desirable substantially solid material that vary widely. For example, the type of surfaces that can be treated with the compositions of this disclosure includes glass; ceramics, such as, silicon nitride, silicon carbide, silica, alumina, zirconia, and the like; metals, such as, iron, stainless steel, galvanized steel, zinc, aluminum, nickel, copper, magnesium and alloys thereof, silver and gold and the like. The surface or substrate contemplated herein may also comprise at least two layers of materials. One layer of material, for example, may include glass, metal, ceramic, composite material. Other layers of material comprising the surface or substrate may include layers of polymers, monomers, organic compounds, inorganic compounds, organometallic compounds, continuous layers and nano-porous layers. The substrate may be a semiconductor device comprising indium gallium zinc oxide (IGZO).

Further, the surfaces and substrates may have different shapes, e.g., substrates having flat, planar surfaces, molded articles having curved surfaces, fibers, fabrics, and the like. It will be appreciated by those skilled in the art that the foregoing lists are merely illustrative of various materials which may be coated using the presently disclosed compositions and methods and are not in any way limiting of the different substrates with which the present disclosure is useful. Insofar as they protect virtually any type of substrate from oxidative thermal degradation, corrosion, or chemical attack. The coatings may also be used to strengthen relatively flaw sensitive brittle substrates such as glass and non-wetting surfaces. The coatings may additionally be useful to provide bonding or compatibility interfaces between different types of materials.

### B. Final Curing

Final curing is the process of polymerization that occurs after the coating composition is applied to the substrate. The silicon-containing precursors described in Section III above may be combined with the catalysts in Section IV that promote a condensation reaction. The condensation reaction occurs between hydroxyl groups on the silicon-containing precursors thus eliminating water molecules from the polymer chain.

The coating compositions may be fully cured to the substrate at an elevated temperature of 200° C., 210° C., 220° C., 230° C., 240° C., 250° C., 260° C., 270° C., 280° C., 290° C., 300° C., 310° C., 320° C., 330° C., 340° C., 350° C., or within any range encompassed by any two of the foregoing values as endpoints. For example, the coatings may be cured at a temperature of from 250° C. to 300° C., or from 270° C., to 330° C.

The curing step may take 15 minutes, 30 minutes, 1 hour, 1.5 hours, or 2 hours, or within any range encompassed by any two of the foregoing values as endpoints. For example, the curing step may take from 30 minutes to 2 hours, or from 1 hour to 2 hours.

The curing step may also be conducted in air or other non-reactive or reactive gaseous environments which contain moisture, inert gases like nitrogen and argon, and reactive gases such as ammonia, hydrogen, carbon monoxide, and the like.

### C. Silanol Groups and SiOH Loss

The silicon-containing precursors described in Section I above may be combined with a catalyst that promotes the hydrolysis reaction and/or the condensation reaction. The condensation reaction occurs at the hydroxyl on the silanol (SiOH) groups, thus eliminating water molecules from the polymer chain.

As noted above, the consumption of silanol (SiOH) groups prior to the final deposition and curing of the coating compositions on substrates helps minimize damage to moisture sensitive layers. It is desirable to minimize the silanol (SiOH) group loss during final curing to in turn minimize moisture release during final curing.

As defined herein, the silanol group (SiOH) loss during final curing may be less than 0.3, less than 0.275, less than 0.25, less than 0.225, less than 0.2, less than 0.175, less than 0.15, less than 0.125, less than 0.1, less than 0.075, less than 0.05, less than 0.0125, less than 0.01, or less than 0.0075.

The amount of moisture release during final curing may also be measured via the following method.

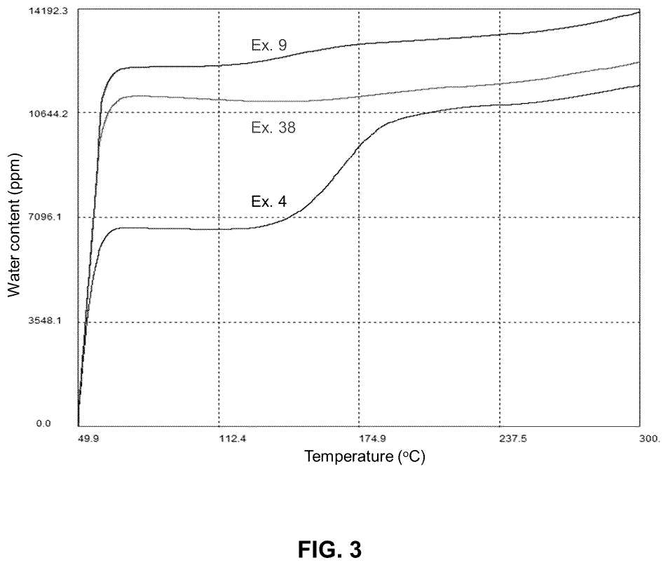

Moisture content in a sample is measured using indirect coulometric Karl Fischer (KF) titration with a KF oven, utilizing the ECH-Aqua 40.00 with a Head Space VARIO module and an autosampler. The titration is performed in a coulometric titration cell with a generator electrode without a diaphragm. A sample size of 0.65 g 20% polysiloxane solution is used, with the KF-oven temperature gradient set from 50-300° C. at a rate of 1° C./min, followed by isothermal heating at 300° C. for 40 minutes. Dried air, passed through molecular sieves (3 A), is used as the carrier gas to ensure dryness. Moisture outgassing from 50˜75 C is mainly free water from the solutions, and condensation moisture is observed after 75 C, wherein the moisture content of the polymers is defined as the difference between the total moisture outgassing and the moisture outgassing from 50˜75° C. FIG. 3 shows the moisture content measurement as described above for exemplary compositions of Examples 4, 9 and 38 below.

### D. Crack-Free Thickness

Crack-free thickness refers to the maximum thickness at which a coating can be applied to a substrate without developing cracks during the curing process. The crack-free thickness of the coating may be improved by changing the chemical composition, such as increasing aryl/alkyl groups ratio, adding difunctional silicone monomers, bipodal silicone monomers in the coating composition.

Herein and in the Examples below, crack-free thickness is determined by the following method.

The coating composition is filtered through a 0.1-micron filter for coating. The filtered coating composition is coated on a four-inch silicon wafer by spin coating at 1,500 revolutions per minute (RPM). The wafer with the cast film is treated with heat on a first hot plate having a surface temperature of 80° C. for 60 seconds and then heat treated on a second hot plate having a surface temperature of 160° C. for 120 seconds, to evaporate the solvents. Film thickness of the coating is measured by ellipsometer. The heat treated wafer is further cured in an air ambient at 300° C. for four cycles, each lasting 1 hour. Subsequently, the film is inspected under an optical microscope for any cracks. Spin coating speed is adjusted to obtain coatings with different thickness on four-inch wafers for same crack inspection after same heating process. The maximum thickness achieved without any cracks is the crack-free thickness.

The coating composition of the present disclosure may have a crack-free thickness from about 1 μm, about 2 μm, or about 3 μm to about 10 μm, about 15 μm, or about 20 μm, or any range using any two of the foregoing values as endpoints, such as from about 1 μm to about 20 μm, about 2 μm to about 15 μm, or about 3 μm to about 10 μm, as determined according to the method described above.

### EXAMPLES

### I. Exemplary Coating Formulations and Results (Examples 1-37)

### Example 1—GR950F Poly(silsesquioxane) Resin

In 100 ml flask, 0.5 g of tetramethylammonium nitrate (TMAN) catalyst was added to 24.5 g of deionized water and stirred for 1 hour at room temperature to prepare a 2 wt. % TMAN catalyst solution. In a 250 ml flask, 10 g of BYK®-307 surfactant obtained from BK-Chemie was added to 90 g of ethanol and stirred for 1 hour at room temperature to prepare a 10 wt. % surfactant solution. In another 250 ml flask, 20.0 g of GR950F resin obtained from Techneglas of Perrysburg, Ohio was added to 80.0 g of PGMEA and stirred for 1 hour at room temperature to form a GR950F resin solution. GR950 was a poly(silsesquioxane) resin including only poly(phenylsilsesquioxane) blocks. 1.25 g of the 10 wt. % surfactant solution and 0.8 g of the 2 wt. % TMAN catalyst solution were added to 100 g of the resin solution and stirred for 3 hours at room temperature to form a coating composition. The coating composition was filtered through a 0.1-micron filter for coating.

The filtered coating composition was coated on a four-inch silicon wafer by spin coating at 1,500 revolutions per minute (RPM). The wafer with the cast film was baked on a first hot plate having a surface temperature of 80° C. for 60 seconds and then baked on a second hot plate having a surface temperature of 160° C. for 120 seconds, to evaporate the solvents. Film thickness of the coating were measured by ellipsometer, the film was about 5621 A thick after baking. The baked wafer was further cured in a nitrogen ambient at 300° C. for 1 hour. Film thickness was 4921 A after curing. Moisture outgassing from the resin was evaluated by the loss of SiOH during the film curing. Amount of SiOH was calculated based on the normalized area of SiOH peak in FT-IR spectrum (the peak area between 839 cm-1-980 cm⁻¹ divided by thickness of the film). Calculated SiOH loss was 0.296.

### Example 2—GR650F Poly(silsesquioxane) Resin

In 100 ml flask, 0.5 g of tetramethylammonium nitrate (TMAN) catalyst was added to 24.5 g of deionized water and stirred for 1 hour at room temperature to prepare a 2 wt. % TMAN catalyst solution. In a 250 ml flask, 10 g of BYK®-307 surfactant obtained from BK-Chemie was added to 90 g of ethanol and stirred for 1 hour at room temperature to prepare a 10 wt. % surfactant solution. In another 250 ml flask, 20.0 g of GR650F resin obtained from Techneglas of Perrysburg, Ohio was added to 80.0 g of PGMEA and stirred for 1 hour at room temperature to form a GR650F resin solution. GR650 was a poly(silsesquioxane) resin including only poly(methylsilsesquioxane) blocks. 1.25 g of the 10 wt. % surfactant solution and 0.8 g of the 2 wt. % TMAN catalyst solution were added to 100 g of the resin solution and stirred for 3 hours at room temperature to form a coating composition. The coating composition was filtered through a 0.1-micron filter for coating.

The filtered coating composition was coated on a four-inch silicon wafer by spin coating at 1,500 revolutions per minute (RPM). The wafer with the cast film was baked on a first hot plate having a surface temperature of 80° C. for 60 seconds and then baked on a second hot plate having a surface temperature of 160° C. for 120 seconds, to evaporate the solvents. Film thickness of the coating was about 6220 A. The baked wafer was further cured in a nitrogen ambient at 300° C. for 1 hour. Film thickness was 5006 A. Calculated SiOH loss during film curing was 0.248.

### Example 3—GR100F Poly(silsesquioxane) Resin

In 100 ml flask, 0.5 g of tetramethylammonium nitrate (TMAN) catalyst was added to 24.5 g of deionized water and stirred for 1 hour at room temperature to prepare a 2 wt. % TMAN catalyst solution. In a 250 ml flask, 10 g of BYK®-307 surfactant obtained from BK-Chemie was added to 90 g of ethanol and stirred for 1 hour at room temperature to prepare a 10 wt. % surfactant solution. In another 250 ml flask, 20.0 g of GR100F resin obtained from Techneglas of Perrysburg, Ohio was added to 80.0 g of PGMEA and stirred for 1 hour at room temperature to form a GR100F resin solution. GR100 was a poly(silsesquioxane) resin including 70% (molar %) of poly(methylsilsesquioxane) blocks and 30% (molar %) of poly(phenylsilsesquioxane) blocks. 1.25 g of the 10 wt. % surfactant solution and 0.8 g of the 2 wt. % TMAN catalyst solution were added to 100 g of the resin solution and stirred for 3 hours at room temperature to form a coating composition. The coating composition was filtered through a 0.1-micron filter for coating.

The filtered coating composition was coated on a four-inch silicon wafer by spin coating at 1,500 revolutions per minute (RPM). The wafer with the cast film was baked on a first hot plate having a surface temperature of 80° C. for 60 seconds and then baked on a second hot plate having a surface temperature of 160° C. for 120 seconds, to evaporate the solvents. Film thickness of the coating was about 6169 A. The baked wafer was further cured in a nitrogen ambient at 300° C. for 1 hour. Film thickness was 5467 A. Calculated SiOH loss during film curing was 0.134.

### Example 4—GR150F Poly(silsesquioxane) Resin

In 100 ml flask, 0.5 g of tetramethylammonium nitrate (TMAN) catalyst was added to 24.5 g of deionized water and stirred for 1 hour at room temperature to prepare a 2 wt. % TMAN catalyst solution. In a 250 ml flask, 10 g of BYK®-307 surfactant obtained from BK-Chemie was added to 90 g of ethanol and stirred for 1 hour at room temperature to prepare a 10 wt. % surfactant solution. In another 250 ml flask, 20.0 g of GR150F resin obtained from Techneglas of Perrysburg, Ohio was added to 80.0 g of PGMEA and stirred for 1 hour at room temperature to form a GR150F resin solution. GR150F was a poly(silsesquioxane) resin including equimolar amounts of poly(methylsilsesquioxane) blocks and poly(phenylsilsesquioxane) blocks with about 0.3 mole % of poly(dimethylsiloxane) blocks. 1.25 g of the 10 wt. % surfactant solution and 0.8 g of the 2 wt. % TMAN catalyst solution were added to the 100 g of the resin solution and stirred for 3 hours at room temperature to form a coating composition. The coating composition was filtered through a 0.1-micron filter for coating.

The filtered coating composition was coated on a four-inch silicon wafer by spin coating at 1,500 revolutions per minute (RPM). The wafer with the cast film was baked on a first hot plate having a surface temperature of 80° C. for 60 seconds and then baked on a second hot plate having a surface temperature of 160° C. for 120 seconds, to evaporate the solvents. Film thickness of the coating was about 6063 A. The baked wafer was further cured in a nitrogen ambient at 300° C. for 1 hour. Film thickness was 5948 A. Calculated SiOH loss during film curing was 0.139.

### Example 5—GR950F/GR150F Poly(silsesquioxane) Resin

In 100 ml flask, 0.5 g of tetramethylammonium nitrate (TMAN) catalyst was added to 24.5 g of deionized water and stirred for 1 hour at room temperature to prepare a 2 wt. % TMAN catalyst solution. In a 250 ml flask, 10 g of BYK®-307 surfactant obtained from BK-Chemie was added to 90 g of ethanol and stirred for 1 hour at room temperature to prepare a 10 wt. % surfactant solution. In another 250 ml flask, 20.0 g of GR950F resin was added to 80.0 g of PGMEA and stirred for 1 hour at room temperature to form a GR950F resin solution. In another 250 ml flask, 20.0 g of GR150F resin was added to 80.0 g of PGMEA and stirred for 1 hour at room temperature to form a GR150F resin solution. In another 250 ml flask, 65.0 g 20% GR150F solution and 35.0 g 20% GR950F solution were added, then 1.25 g of the 10 wt. % surfactant solution and 0.8 g of the 2 wt. % TMAN catalyst solution were added to the 100 g of the GR150F/GR950F resin solution and stirred for 3 hours at room temperature to form a coating composition. The coating composition was filtered through a 0.1-micron filter for coating.

The filtered coating composition was coated on a four-inch silicon wafer by spin coating at 1,500 revolutions per minute (RPM). The wafer with the cast film was baked on a first hot plate having a surface temperature of 80° C. for 60 seconds and then baked on a second hot plate having a surface temperature of 160° C. for 120 seconds, to evaporate the solvents. Film thickness of the coating was about 7283 A. The baked wafer was further cured in a nitrogen ambient at 300° C. for 1 hour. Film thickness was 7139 A. Calculated SiOH loss during film curing was 0.217.

### Example 6—GR150F Poly(silsesquioxane) Resin with Higher Molecular Weight

In a 250 ml flask, 20.0 g of GR150F-HMW resin obtained from Techneglas of Perrysburg, Ohio was added to 80.0 g of PGMEA and stirred for 1 hour at room temperature to form a coating composition. GR150F-HMW was a poly(silsesquioxane) resin same as GR150F but with higher molecular weight. Molecular weight of the resin was measured on Gel permeation chromatography (GPC), Weight average molecular weight (Mw) of the resin was about 6009 Dalton. The coating composition was filtered through a 0.1-micron filter for coating.

The filtered coating composition was coated on a four-inch silicon wafer by spin coating at 1,500 revolutions per minute (RPM). The wafer with the cast film was baked on a first hot plate having a surface temperature of 80° C. for 60 seconds and then baked on a second hot plate having a surface temperature of 160° C. for 120 seconds, to evaporate the solvents. Film thickness of the coating was about 6274 A. The baked wafer was further cured in a nitrogen ambient at 300° C. for 1 hour. Film thickness was 5449 A. Calculated SiOH loss during film curing was 0.104.

### Example 7—Pre-Condensed GR150F Poly(silsesquioxane) Resin

In a 250 ml flask, 100 g of 20% GR100F resin solution was made by using the method described above in Example 3. 1.25 g of the 10 wt. % surfactant solution and 0.8 g of the 2 wt. % TMAN catalyst solution were added to the flask. The solution was heated to refluxing for 90 minutes to form a coating composition. The coating composition was cooled down to room temperature and filtered through a 0.1-micron filter for coating. Molecular weight of was measured on Gel permeation chromatography (GPC), Weight average molecular weight (Mw) of the resin was about 13510 Dalton after pre-condensing.

The filtered coating composition was coated on a four-inch silicon wafer by spin coating at 1,500 revolutions per minute (RPM). The wafer with the cast film was baked on a first hot plate having a surface temperature of 80° C. for 60 seconds and then baked on a second hot plate having a surface temperature of 160° C. for 120 seconds, to evaporate the solvents. Film thickness of the coating was about 6583 A. The baked wafer was further cured in a nitrogen ambient at 300° C. for 1 hour. Film thickness was 6546 A. Calculated SiOH loss during film curing was 0.020.

### Example 8—Pre-Condensed GR150F Poly(silsesquioxane) Resin

In a 250 ml flask, 100 g of 20% GR100F resin solution was made by using the method described above in Example 3. 1.25 g of the 10 wt. % surfactant solution and 0.8 g of the 2 wt. % TMAN catalyst solution were added to the flask. The solution was heated to refluxing for 180 minutes to form a coating composition. The coating composition was cooled down to room temperature and filtered through a 0.1-micron filter for coating. Molecular weight of was measured on Gel permeation chromatography (GPC), Weight average molecular weight (Mw) of the resin was about 36271 Dalton after pre-condensing.

The filtered coating composition was coated on a four-inch silicon wafer by spin coating at 1,500 revolutions per minute (RPM). The wafer with the cast film was baked on a first hot plate having a surface temperature of 80° C. for 60 seconds and then baked on a second hot plate having a surface temperature of 160° C. for 120 seconds, to evaporate the solvents. Film thickness of the coating was about 7565 A. The baked wafer was further cured in a nitrogen ambient at 300° C. for 1 hour. Film thickness was 7546 A. Calculated SiOH loss during film curing was 0.012.

### Example 9—Pre-Condensed GR150F Poly(silsesquioxane) Resin

In 100 ml flask, 0.5 g of tetramethylammonium nitrate (TMAN) catalyst was added to 24.5 g of deionized water and stirred for 1 hour at room temperature to prepare a 2 wt. % TMAN catalyst solution. In a 250 ml flask, 10 g of BYK®-307 surfactant obtained from BK-Chemie was added to 90 g of ethanol and stirred for 1 hour at room temperature to prepare a 10 wt. % surfactant solution. In another 250 ml flask, 20.8 g of GR150F resin was added to 83.3 g of PGMEA and stirred for 1 hour at room temperature to form a GR150F resin solution. 0.15 g of the 10 wt. % surfactant solution, 0.84 g of the 2 wt. % TMAN catalyst solution were added to the 104.1 g of the resin solution, the solution was heated to refluxing for 45 min, then cooled down to RT, the solution was subject to a second pre-condensing at refluxing for 15 min. The coating composition was cooled down to room temperature and filtered through a 0.1-micron filter for coating.

Molecular weight of was measured on Gel permeation chromatography (GPC), Weight average molecular weight (Mw) of the resin was about 32070 Dalton after pre-condensing.

The filtered coating composition was coated on a four-inch silicon wafer by spin coating at 1,500 revolutions per minute (RPM). The wafer with the cast film was baked on a first hot plate having a surface temperature of 80° C. for 60 seconds and then baked on a second hot plate having a surface temperature of 160° C. for 120 seconds, to evaporate the solvents. Film thickness of the coating was about 7026 A. The baked wafer was further cured in a nitrogen ambient at 300° C. for 1 hour. Film thickness was 7060. Calculated SiOH loss during film curing was 0.015.

### Example 10—GR150F Poly(Silsesquioxane) Resin Pre-Condensed with MTAS

In a 250 ml flask, 100 g of 20% GR100F resin solution was made by using the method described above in Example 3. 2.0 g Methyltriacetoxysilane (MTAS) was added to the resin solution as water scavenger to capture the H2O generated during the SiOH condensation. 1.25 g of the 10 wt. % surfactant solution and 0.8 g of the 2 wt. % TMAN catalyst solution were added to the flask. The solution was heated to refluxing for 90 minutes to form a coating composition. The coating composition was cooled down to room temperature and filtered through a 0.1-micron filter for coating.

The filtered coating composition was coated on a four-inch silicon wafer by spin coating at 1,500 revolutions per minute (RPM). The wafer with the cast film was baked on a first hot plate having a surface temperature of 80° C. for 60 seconds and then baked on a second hot plate having a surface temperature of 160° C. for 120 seconds, to evaporate the solvents. Film thickness of the coating was about 6298 A. The baked wafer was further cured in a nitrogen ambient at 300° C. for 1 hour. Film thickness was 6287 A. Calculated SiOH loss during film curing was 0.045, showing lower moisture outgassing than the GR150F-HMW film which has similar Mw but no MATS in the composition.

### Example 11—GR950F/GR150F Poly(silsesquioxane) Coating with Different Baking

The same GR950F/GR150F coating composition prepared by using the method described above in example 5 was coated on a four-inch silicon wafer by spin coating at 1,500 revolutions per minute (RPM). The wafer with the cast film was baked on a hot plate having a surface temperature of 80° C. for 60 seconds, to evaporate the solvents. Film thickness of the coating was about 7399 A. The baked wafer was cured in a nitrogen ambient at 300° C. for 1 hour. Film thickness was 7156 A. Calculated SiOH loss during film curing was 0.2418.

### Example 12—GR150F Poly(silsesquioxane) Coating with Different Baking

In 100 ml flask, 0.5 g of tetramethylammonium nitrate (TMAN) catalyst was added to 24.5 g of deionized water and stirred for 1 hour at room temperature to prepare a 2 wt. % TMAN catalyst solution. In a 250 ml flask, 10 g of BYK®-307 surfactant obtained from BK-Chemie was added to 90 g of ethanol and stirred for 1 hour at room temperature to prepare a 10 wt. % surfactant solution. In another 250 ml flask, 20.8 g of GR150F resin was added to 83.3 g of PGMEA and stirred for 1 hour at room temperature to form a GR150F resin solution. 0.15 g of the 10 wt. % surfactant solution, 0.84 g of the 2 wt. % TMAN catalyst solution and 0.84 g vinyltriethoxysilane were added to the 104.1 g of the resin solution and stirred for 3 hours at room temperature to form a coating composition. The coating composition was filtered through a 0.1-micron filter for coating.

The coating composition was coated on a four-inch silicon wafer by spin coating at 1,000 revolutions per minute (RPM). The wafer with the cast film was baked on a first hot plate having a surface temperature of 80° C. for 60 seconds and then baked on a second hot plate having a surface temperature of 160° C. for 60 seconds, to evaporate the solvents. Film thickness of the coating was about 7367 A. The baked wafer was further cured in a nitrogen ambient at 300° C. for 1 hour. Film thickness was 7218 A. Calculated SiOH loss during film curing was 0.165.

### Example 13—GR150F Poly(silsesquioxane) Coating with Different Baking

The same GR150F coating composition prepared by using the method described above in example 12 was coated on a four-inch silicon wafer by spin coating at 1,000 revolutions per minute (RPM). The wafer with the cast film was baked on a first hot plate having a surface temperature of 80° C. for 60 seconds and then baked on a second hot plate having a surface temperature of 160° C. for 120 seconds, to evaporate the solvents. Film thickness of the coating was about 7340 A. The baked wafer was further cured in a nitrogen ambient at 300° C. for 1 hour. Film thickness was 7214 A. Calculated SiOH loss during film curing was 0.146.

### Example 14—GR150F Poly(silsesquioxane) Coating with Different Baking

The same GR150F coating composition prepared by using the method described above in example 12 was coated on a four-inch silicon wafer by spin coating at 1,000 revolutions per minute (RPM). The wafer with the cast film was baked on a first hot plate having a surface temperature of 80° C. for 60 seconds and then baked on a second hot plate having a surface temperature of 160° C. for 300 seconds, to evaporate the solvents. Film thickness of the coating was about 7311 A. The baked wafer was further cured in a nitrogen ambient at 300° C. for 1 hour. Film thickness was 7252 A. Calculated SiOH loss during film curing was 0.076.

### Example 15—GR150F Poly(silsesquioxane) Coating with Different Baking

The same GR150F coating composition prepared by using the method described above in example 12 was coated on a four-inch silicon wafer by spin coating at 1,000 revolutions per minute (RPM). The wafer with the cast film was baked on a first hot plate having a surface temperature of 80° C. for 60 seconds and then baked on a second hot plate having a surface temperature of 160° C. for 600 seconds, to evaporate the solvents. Film thickness of the coating was about 7284 A. The baked wafer was further cured in a nitrogen ambient at 300° C. for 1 hour. Film thickness was 7296 A. Calculated SiOH loss during film curing was 0.013.

### Example 16-GR150F Poly(silsesquioxane) Coating with Different Baking

The same GR150F coating composition prepared by using the method described above in example 12 was coated on a four-inch silicon wafer by spin coating at 1,000 revolutions per minute (RPM). The wafer with the cast film was baked on a first hot plate having a surface temperature of 80° C. for 60 seconds and then baked on a second hot plate having a surface temperature of 180° C. for 60 seconds, to evaporate the solvents. Film thickness of the coating was about 7377 A. The baked wafer was further cured in a nitrogen ambient at 300° C. for 1 hour. Film thickness was 7223 A. Calculated SiOH loss during film curing was 0.152.

### Example 17-GR150F Poly(silsesquioxane) Coating with Different Baking

The same GR150F coating composition prepared by using the method described above in example 12 was coated on a four-inch silicon wafer by spin coating at 1,000 revolutions per minute (RPM). The wafer with the cast film was baked on a first hot plate having a surface temperature of 80° C. for 60 seconds and then baked on a second hot plate having a surface temperature of 180° C. for 120 seconds, to evaporate the solvents. Film thickness of the coating was about 7334 A. The baked wafer was further cured in a nitrogen ambient at 300° C. for 1 hour. Film thickness was 7265 A. Calculated SiOH loss during film curing was 0.069.

### Example 18-GR150F Poly(silsesquioxane) Coating with Different Baking

The same GR150F coating composition prepared by using the method described above in example 12 was coated on a four-inch silicon wafer by spin coating at 1,000 revolutions per minute (RPM). The wafer with the cast film was baked on a first hot plate having a surface temperature of 80° C. for 60 seconds and then baked on a second hot plate having a surface temperature of 180° C. for 300 seconds, to evaporate the solvents. Film thickness of the coating was about 7293 A. The baked wafer was further cured in a nitrogen ambient at 300° C. for 1 hour. Film thickness was 7311 A. Calculated SiOH loss during film curing was 0.012.

### Example 19-GR150F Poly(silsesquioxane) Coating with Different Baking

The same GR150F coating composition prepared by using the method described above in example 12 was coated on a four-inch silicon wafer by spin coating at 1,000 revolutions per minute (RPM). The wafer with the cast film was baked on a first hot plate having a surface temperature of 80° C. for 60 seconds and then baked on a second hot plate having a surface temperature of 180° C. for 600 seconds, to evaporate the solvents. Film thickness of the coating was about 7288 A. The baked wafer was further cured in a nitrogen ambient at 300° C. for 1 hour. Film thickness was 7312 A. Calculated SiOH loss during film curing was 0.005.

### Example 20—Further Pre-Condensed GR150F Poly(silsesquioxane) with 3% DPDS

In a 250 ml flask, 100 g of 20% pre-condensed GR150F Poly(silsesquioxane) Resin made by using the method described above in Example 7. 0.6 g Diethoxydiphenylsilane (DPDS), SID4525.0 from Gelest, was added to the resin solution to increase the permissible crack-free thickness of the resulting films after a coating formulation. The solution was heated to refluxing for 1 hr to form a coating composition. The coating composition was cooled down to room temperature and filtered through 0.45-micron and 0.1-micron filters for coating. The filtered coating composition was coated on a four-inch silicon wafer by spin coating at 1,500 revolutions per minute (RPM). The wafer with the cast film was baked on a first hot plate having a surface temperature of 80° C. for 60 seconds and then baked on a second hot plate having a surface temperature of 160° C. for 120 seconds, to evaporate the solvents. Film thickness of the coating was about 6739 A. This formulation shows higher crack-free thickness (5.7 μm) than the GR150F film which has similar Mw but no DPDS in the composition.

### Example 21—Further Pre-Condensed GR150F Poly(silsesquioxane) with 10% DPDS

In a 250 ml flask, 100 g of 20% pre-condensed GR150F Poly(silsesquioxane) Resin made by using the method described above in Example 7. 2 g Diethoxydiphenylsilane (DPDS), SID4525.0 from Gelest, was added to the resin solution to increase the permissible crack-free thickness of the resulting films after a coating formulation. The solution was heated to refluxing for 1 hr to form a coating composition. The coating composition was cooled down to room temperature and filtered through 0.45-micron and 0.1-micron filters for coating. The filtered coating composition was coated on a four-inch silicon wafer by spin coating at 1,500 revolutions per minute (RPM). The wafer with the cast film was baked on a first hot plate having a surface temperature of 80° C. for 60 seconds and then baked on a second hot plate having a surface temperature of 160° C. for 120 seconds, to evaporate the solvents. Film thickness of the coating was about 9664 A. This formulation shows higher crack-free thickness (5.4 μm) than the GR150F film which has similar Mw but no DPDS in the composition.

### Example 22—Further Pre-Condensed GR150F Poly(silsesquioxane) with 10% MPDS

In a 250 ml flask, 100 g of 20% pre-condensed GR150F Poly(silsesquioxane) Resin made by using the method described above in Example 7. 2 g Methyl-phenyl-diethoxysilane (MPDS) SIP6740.0 from Gelest, were added to the resin solution to increase the permissible crack-free thickness of the resulting films after a coating formulation. The solution was heated to refluxing for 1 hr to form a coating composition. The coating composition was cooled down to room temperature and filtered through 0.45-micron and 0.1-micron filters for coating. The filtered coating composition was coated on a four-inch silicon wafer by spin coating at 1,500 revolutions per minute (RPM). The wafer with the cast film was baked on a first hot plate having a surface temperature of 80° C. for 60 seconds and then baked on a second hot plate having a surface temperature of 160° C. for 120 seconds, to evaporate the solvents. Film thickness of the coating was about 9117 A. This formulation shows higher crack-free thickness (5.4 μm) than the GR150F film which has similar Mw but no MPDS in the composition.

### Example 23—Further Pre-Condensed GR150F Poly(silsesquioxane) with 3% DPDS and 1% MPDS

In a 250 ml flask, 100 g of 20% pre-condensed GR150F Poly(silsesquioxane) Resin made by using the method described above in Example 7. 0.6 g Diethoxydiphenylsilane (DPDS) SID4525.0 and 0.2 g Methyl-phenyl-diethoxysilane (MPDS) SIP6740.0 from Gelest, were added to the resin solution to increase the permissible crack-free thickness of the resulting films after a coating formulation. The solution was heated to refluxing for 1 hr to form a coating composition. The coating composition was cooled down to room temperature and filtered through 0.45-micron and 0.1-micron filters for coating. The filtered coating composition was coated on a four-inch silicon wafer by spin coating at 1,500 revolutions per minute (RPM). The wafer with the cast film was baked on a first hot plate having a surface temperature of 80° C. for 60 seconds and then baked on a second hot plate having a surface temperature of 160° C. for 120 seconds, to evaporate the solvents. Film thickness of the coating was about 6443 A. This formulation shows higher crack-free thickness (5.7 μm) than the GR150F film which has similar Mw but no DPDS or MPDS in the composition.

### Example 24—Further Pre-Condensed GR150F Poly(silsesquioxane) with 5% DPDS and 5% MPDS

In a 250 ml flask, 100 g of 20% pre-condensed GR150F Poly(silsesquioxane) Resin made by using the method described above in Example 7. 1 g Diethoxydiphenylsilane (DPDS) SID4525.0 and 1 g Methyl-phenyl-diethoxysilane (MPDS) SIP6740.0 from Gelest, were added to the resin solution to increase the permissible crack-free thickness of the resulting films after a coating formulation. The solution was heated to refluxing for 1 hr to form a coating composition. The coating composition was cooled down to room temperature and filtered through 0.45-micron and 0.1-micron filters for coating. The filtered coating composition was coated on a four-inch silicon wafer by spin coating at 1,500 revolutions per minute (RPM). The wafer with the cast film was baked on a first hot plate having a surface temperature of 80° C. for 60 seconds and then baked on a second hot plate having a surface temperature of 160° C. for 120 seconds, to evaporate the solvents. Film thickness of the coating was about 9015 A. This formulation shows higher crack-free thickness (5.4 μm) than the GR150F film which has similar Mw but no DPDS or MPDS in the composition.

### Example 25—Further Pre-Condensed GR150F Poly(silsesquioxane) with 3% DPDS and 1% DMDS

In a 250 ml flask, 100 g of 20% pre-condensed GR150F Poly(silsesquioxane) Resin made by using the method described above in Example 7. 0.6 g Diethoxydiphenylsilane (DPDS) SID4525.0 and 0.2 g Diethoxydimethylsilane (DMDS) SIP6740.0 from Gelest, were added to the resin solution to increase the permissible crack-free thickness of the resulting films after a coating formulation. The solution was heated to refluxing for 1 hr to form a coating composition. The coating composition was cooled down to room temperature and filtered through 0.45-micron and 0.1-micron filters for coating. The filtered coating composition was coated on a four-inch silicon wafer by spin coating at 1,500 revolutions per minute (RPM). The wafer with the cast film was baked on a first hot plate having a surface temperature of 80° C. for 60 seconds and then baked on a second hot plate having a surface temperature of 160° C. for 120 seconds, to evaporate the solvents. Film thickness of the coating was about 7067 A. This formulation shows higher crack-free thickness (5.4 μm) than the GR150F film which has similar Mw but no DPDS or DMDS in the composition.

### Example 26—Further Pre-Condensed GR150F Poly(silsesquioxane with 1% 1,2-Bis(triethoxyl silyl ethane)

In a 250 ml flask, 100 g of 20% pre-condensed GR150F Poly(silsesquioxane) Resin made by using the method described above in Example 7. 0.2 g 1,2-Bis(triethoxyl silyl ethane) SIB1817.0 from Gelest, were added to the resin solution to increase the permissible crack-free thickness of the resulting films after a coating formulation. The solution was heated to refluxing for 1 hr to form a coating composition. The coating composition was cooled down to room temperature and filtered through 0.45-micron and 0.1-micron filters for coating. The filtered coating composition was coated on a four-inch silicon wafer by spin coating at 1,500 revolutions per minute (RPM). The wafer with the cast film was baked on a first hot plate having a surface temperature of 80° C. for 60 seconds and then baked on a second hot plate having a surface temperature of 160° C. for 120 seconds, to evaporate the solvents. Film thickness of the coating was about 6608 A. This formulation shows higher crack-free thickness (6.8 μm) than the GR150F film which has similar Mw but no 1,2-Bis(triethoxyl silyl ethane) in the composition.

### Example 27—Further Pre-Condensed GR150F Poly(silsesquioxane) with 0.5% 1,4-Bis(triethoxysilyl)benzene

In a 250 ml flask, 100 g of 20% pre-condensed GR150F Poly(silsesquioxane) Resin made by using the method described above in Example 7. 0.1 g 1,4-Bis(triethoxysilyl)benzene SIB1816.6 from Gelest, were added to the resin solution to increase the permissible crack-free thickness of the resulting films after a coating formulation. The solution was heated to refluxing for 1 hr to form a coating composition. The coating composition was cooled down to room temperature and filtered through 0.45-micron and 0.1-micron filters for coating. The filtered coating composition was coated on a four-inch silicon wafer by spin coating at 1,500 revolutions per minute (RPM). The wafer with the cast film was baked on a first hot plate having a surface temperature of 80° C. for 60 seconds and then baked on a second hot plate having a surface temperature of 160° C. for 120 seconds, to evaporate the solvents. Film thickness of the coating was about 7195 A. This formulation shows higher crack-free thickness (6.5 μm) than the GR150F film which has similar Mw but no 1,4-Bis(triethoxysilyl)benzene in the composition.

### Example 28—Further Pre-Condensed GR150F Poly(silsesquioxane) with 0.5% Bis(triethoxysilyl)octane

In a 250 ml flask, 100 g of 20% pre-condensed GR150F Poly(silsesquioxane) Resin made by using the method described above in Example 7. 0.1 g 1,8-Bis(triethoxysilyl)octane SIB1824.0 from Gelest, were added to the resin solution to increase the permissible crack-free thickness of the resulting films after a coating formulation. The solution was heated to refluxing for 1 hr to form a coating composition. The coating composition was cooled down to room temperature and filtered through 0.45-micron and 0.1-micron filters for coating. The filtered coating composition was coated on a four-inch silicon wafer by spin coating at 1,500 revolutions per minute (RPM). The wafer with the cast film was baked on a first hot plate having a surface temperature of 80° C. for 60 seconds and then baked on a second hot plate having a surface temperature of 160° C. for 120 seconds, to evaporate the solvents. Film thickness of the coating was about 10881 A. This formulation shows higher crack-free thickness (6.5 μm) than the GR150F film which has similar Mw but no Bis(triethoxysilyl)octane in the composition.

### Example 29—Further Pre-Condensed GR150F Poly(silsesquioxane) with 1% Bis(triethoxysilyl)octane

In a 250 ml flask, 100 g of 20% pre-condensed GR150F Poly(silsesquioxane) Resin made by using the method described above in Example 7. 0.2 g 1,8-Bis(triethoxysilyl)octane SIB1824.0 from Gelest, were added to the resin solution to increase the permissible crack-free thickness of the resulting films after a coating formulation. The solution was heated to refluxing for 1 hr to form a coating composition. The coating composition was cooled down to room temperature and filtered through 0.45-micron and 0.1-micron filters for coating. The filtered coating composition was coated on a four-inch silicon wafer by spin coating at 1,500 revolutions per minute (RPM). The wafer with the cast film was baked on a first hot plate having a surface temperature of 80° C. for 60 seconds and then baked on a second hot plate having a surface temperature of 160° C. for 120 seconds, to evaporate the solvents. Film thickness of the coating was about 6730 A. This formulation shows higher crack-free thickness (6.1 μm) than the GR150F film which has similar Mw but no Bis(triethoxysilyl)octane in the composition.

### Example 30—Further Pre-Condensed GR150F Poly(silsesquioxane) with 0.5% 3-Glycidyloxypropyltrimethoxysilane

In a 250 ml flask, 100 g of 20% pre-condensed GR150F Poly(silsesquioxane) Resin made by using the method described above in Example 7. 0.2 g 3-Glycidyloxypropyltrimethoxysilane SIG5840.0 from Gelest, were added to the resin solution to increase the permissible crack-free thickness of the resulting films after a coating formulation. The solution was heated to refluxing for 2 hr to form a coating composition. The coating composition was cooled down to room temperature and filtered through 0.45-micron and 0.1-micron filters for coating. The filtered coating composition was coated on a four-inch silicon wafer by spin coating at 1,500 revolutions per minute (RPM). The wafer with the cast film was baked on a first hot plate having a surface temperature of 80° C. for 60 seconds and then baked on a second hot plate having a surface temperature of 160° C. for 120 seconds, to evaporate the solvents. Film thickness of the coating was about 14163 A. This formulation shows higher crack-free thickness (4.7 μm) than the GR150F film which has similar Mw but no Glycidyloxypropyltrimethoxysilane in the composition.

### Example 31—Pre-Condensed 70% GR908F/30% GR150F Poly(silsesquioxane)

In 100 ml flask, 0.5 g of tetramethylammonium nitrate (TMAN) catalyst was added to 24.5 g of deionized water and stirred for 1 hour at room temperature to prepare a 2 wt. % TMAN catalyst solution. In a 250 ml flask, 10 g of BYK®-307 surfactant obtained from BK-Chemie was added to 90 g of ethanol and stirred for 1 hour at room temperature to prepare a 10 wt. % surfactant solution. In another 250 ml flask, 20.0 g of GR908F resin was added to 80.0 g of PGMEA and stirred for 1 hour at room temperature to form a GR908F resin solution. In another 250 ml flask, 20.0 g of GR150F resin was added to 80.0 g of PGMEA and stirred for 1 hour at room temperature to form a GR150F resin solution. In another 250 ml flask, 70.0 g 20% GR908F solution and 30.0 g 20% GR150F solution were added, then 1.25 g of the 10 wt. % surfactant solution and 0.8 g of the 2 wt. % TMAN catalyst solution were added to the 100 g of the GR908F/GR150F resin solution was heated to refluxing for 45 hr to form a coating composition. The coating composition was filtered through a 0.45-micron and 0.1-micron filters for coating. The filtered coating composition was coated on a four-inch silicon wafer by spin coating at 1,500 revolutions per minute (RPM). The wafer with the cast film was baked on a first hot plate having a surface temperature of 80° C. for 60 seconds and then baked on a second hot plate having a surface temperature of 160° C. for 120 seconds, to evaporate the solvents. Film thickness of the coating was about 7075 A. Calculated SiOH loss during film curing was 0.017. This formulation shows higher crack-free thickness (5.7 μm) than the GR150F film which has similar Mw but no GR908F in the composition.

### Example 32—Further Pre-Condensed 70% GR908F with 30% GR150F Poly(silsesquioxane)

In 100 ml flask, 0.5 g of tetramethylammonium nitrate (TMAN) catalyst was added to 24.5 g of deionized water and stirred for 1 hour at room temperature to prepare a 2 wt. % TMAN catalyst solution. In a 250 ml flask, 10 g of BYK®-307 surfactant obtained from BK-Chemie was added to 90 g of ethanol and stirred for 1 hour at room temperature to prepare a 10 wt. % surfactant solution. In another 250 ml flask, 20.0 g of GR908F resin was added to 80.0 g of PGMEA and was heated to refluxing for 10 hr to form a pre-condensed GR908F resin solution. In another 250 ml flask, 20.0 g of GR150F resin was added to 80.0 g of PGMEA and was heated to refluxing for 5 hr to form a pre-condensed GR150F resin solution. In another 250 ml flask, 70.0 g 20% GR908F solution and 30.0 g 20% GR150F solution were added, then 1.25 g of the 10 wt. % surfactant solution and 0.8 g of the 2 wt. % TMAN catalyst solution were added to the 100 g of the GR908F/GR150F resin solution was heated to refluxing for 15 hr to form a coating composition. The coating composition was filtered through a 0.45-micron and 0.1-micron filters for coating. The filtered coating composition was coated on a four-inch silicon wafer by spin coating at 1,500 revolutions per minute (RPM). The wafer with the cast film was baked on a first hot plate having a surface temperature of 80° C. for 60 seconds and then baked on a second hot plate having a surface temperature of 160° C. for 120 seconds, to evaporate the solvents. Film thickness of the coating was about 7231 A. Calculated SiOH loss during film curing was 0.013. This formulation shows higher crack-free thickness (7.8 μm) than the GR150F film which has similar Mw but no GR908F in the composition.

### Example 33—Pre-Condensed 70% GR908F/30% GR150F Poly(silsesquioxane) with A-1170-TFAA

In 100 ml flask, 0.5 g of tetramethylammonium nitrate (TMAN) catalyst was added to 24.5 g of deionized water and stirred for 1 hour at room temperature to prepare a 2 wt. % TMAN catalyst solution. In a 250 ml flask, 10 g of BYK®-307 surfactant obtained from BK-Chemie was added to 90 g of ethanol and stirred for 1 hour at room temperature to prepare a 10 wt. % surfactant solution. In another 250 ml flask, 20.0 g of GR908F resin was added to 80.0 g of PGMEA and stirred for 1 hour at room temperature to form a GR908F resin solution. In another 250 ml flask, 20.0 g of GR150F resin was added to 80.0 g of PGMEA and stirred for 1 hour at room temperature to form a GR150F resin solution. In another 250 ml flask, 70.0 g 20% GR908F solution and 30.0 g 20% GR150F solution were added, then 1.25 g of the 10 wt. % surfactant solution, 0.2 g A-1170-TFAA and 0.8 g of the 2 wt. % TMAN catalyst solution were added to the 100 g of the GR908F/GR150F resin solution was heated to refluxing for 4 hr to form a coating composition. The coating composition was filtered through a 0.45-micron and 0.1-micron filters for coating. The filtered coating composition was coated on a four-inch silicon wafer by spin coating at 1,500 revolutions per minute (RPM). The wafer with the cast film was baked on a first hot plate having a surface temperature of 80° C. for 60 seconds and then baked on a second hot plate having a surface temperature of 160° C. for 120 seconds, to evaporate the solvents. Film thickness of the coating was about 6910 A. Calculated SiOH loss during film curing was 0.013. This formulation shows higher crack-free thickness (5.6 μm) than the GR150F film which has similar Mw but no GR908F in the composition.

### Example 34—Pre-Condensed 60% GR908F/40% GR150F Poly(silsesquioxane) Resin with A-1170-TFAA

In 100 ml flask, 0.5 g of tetramethylammonium nitrate (TMAN) catalyst was added to 24.5 g of deionized water and stirred for 1 hour at room temperature to prepare a 2 wt. % TMAN catalyst solution. In a 250 ml flask, 10 g of BYK®-307 surfactant obtained from BK-Chemie was added to 90 g of ethanol and stirred for 1 hour at room temperature to prepare a 10 wt. % surfactant solution. In another 250 ml flask, 20.0 g of GR908F resin was added to 80.0 g of PGMEA and stirred for 1 hour at room temperature to form a GR908F resin solution. In another 250 ml flask, 20.0 g of GR150F resin was added to 80.0 g of PGMEA and stirred for 1 hour at room temperature to form a GR150F resin solution. In another 250 ml flask, 60.0 g 20% GR908F solution and 40.0 g 20% GR150F solution were added, then 1.25 g of the 10 wt. % surfactant solution, 0.2 g A-1170-TFAA and 0.8 g of the 2 wt. % TMAN catalyst solution were added to the 100 g of the GR908F/GR150F resin solution was heated to refluxing for 4 hr to form a coating composition. The coating composition was filtered through a 0.45-micron and 0.1-micron filters for coating. The filtered coating composition was coated on a four-inch silicon wafer by spin coating at 1,500 revolutions per minute (RPM). The wafer with the cast film was baked on a first hot plate having a surface temperature of 80° C. for 60 seconds and then baked on a second hot plate having a surface temperature of 160° C. for 120 seconds, to evaporate the solvents. Film thickness of the coating was about 7097 A. Calculated SiOH loss during film curing was 0.018. This formulation shows higher crack-free thickness (5.6 μm) than the GR150F film which has similar Mw but no GR908F in the composition.

### Example 35—Pre-Condensed 60% GR908F/40% GR150F Poly(silsesquioxane) Resin with with 5% MPDS-5% DPDS

In 100 ml flask, 0.5 g of tetramethylammonium nitrate (TMAN) catalyst was added to 24.5 g of deionized water and stirred for 1 hour at room temperature to prepare a 2 wt. % TMAN catalyst solution. In a 250 ml flask, 10 g of BYK®-307 surfactant obtained from BK-Chemie was added to 90 g of ethanol and stirred for 1 hour at room temperature to prepare a 10 wt. % surfactant solution. In another 250 ml flask, 20.0 g of GR908F resin was added to 80.0 g of PGMEA and stirred for 1 hour at room temperature to form a GR908F resin solution. In another 250 ml flask, 20.0 g of GR150F resin was added to 80.0 g of PGMEA and stirred for 1 hour at room temperature to form a GR150F resin solution. In another 250 ml flask, 60.0 g 20% GR908F solution and 40.0 g 20% GR150F solution were added, then 1.25 g of the 10 wt. % surfactant solution, 0.8 g of the 2 wt. % TMAN catalyst solution, and 1 g Diethoxydiphenylsilane (DPDS) and 1 g Methyl-phenyl-diethoxysilane (MPDS) were added to the 100 g of the GR908F/GR150F resin solution was heated to refluxing for 20 hr to form a coating composition. The coating composition was filtered through a 0.45-micron and 0.1-micron filters for coating. The filtered coating composition was coated on a four-inch silicon wafer by spin coating at 1,500 revolutions per minute (RPM). The wafer with the cast film was baked on a first hot plate having a surface temperature of 80° C. for 60 seconds and then baked on a second hot plate having a surface temperature of 160° C. for 120 seconds, to evaporate the solvents. Film thickness of the coating was about 9697 A. Calculated SiOH loss during film curing was 0.014. This formulation shows higher crack-free thickness (10.3 μm) than the GR150F film which has similar Mw but no GR908F or MPDS or DPDS in the composition.

### Example 36—Pre-Condensed 60% GR908F/40% GR150F Poly(silsesquioxane) Resin with with 1% 1,4-Bis(triethoxysilyl)benzene

In 100 ml flask, 0.5 g of tetramethylammonium nitrate (TMAN) catalyst was added to 24.5 g of deionized water and stirred for 1 hour at room temperature to prepare a 2 wt. % TMAN catalyst solution. In a 250 ml flask, 10 g of BYK®-307 surfactant obtained from BK-Chemie was added to 90 g of ethanol and stirred for 1 hour at room temperature to prepare a 10 wt. % surfactant solution. In another 250 ml flask, 20.0 g of GR908F resin was added to 80.0 g of PGMEA and stirred for 1 hour at room temperature to form a GR908F resin solution. In another 250 ml flask, 20.0 g of GR150F resin was added to 80.0 g of PGMEA and stirred for 1 hour at room temperature to form a GR150F resin solution. In another 250 ml flask, 60.0 g 20% GR908F solution and 40.0 g 20% GR150F solution were added, then 1.25 g of the 10 wt. % surfactant solution, 0.8 g of the 2 wt. % TMAN catalyst solution, and 0.2 g 1,4-Bis(triethoxysilyl)benzene were added to the 100 g of the GR908F/GR150F resin solution was heated to refluxing for 2 hr to form a coating composition. The coating composition was filtered through a 0.45-micron and 0.1-micron filters for coating. The filtered coating composition was coated on a four-inch silicon wafer by spin coating at 1,500 revolutions per minute (RPM). The wafer with the cast film was baked on a first hot plate having a surface temperature of 80° C. for 60 seconds and then baked on a second hot plate having a surface temperature of 160° C. for 120 seconds, to evaporate the solvents. Film thickness of the coating was about 8012 A. Calculated SiOH loss during film curing was 0.034. This formulation shows higher crack-free thickness (8.3 μm) than the GR150F film which has similar Mw but no GR908F or Bis(triethoxysilyl)benzene in the composition.

### Example 37—Pre-Condensed 60% GR908F/40% GR150F Poly(silsesquioxane) Resin with with 1% 3-Glycidoxypropyldimethylethoxysilane

In 100 ml flask, 0.5 g of tetramethylammonium nitrate (TMAN) catalyst was added to 24.5 g of deionized water and stirred for 1 hour at room temperature to prepare a 2 wt. % TMAN catalyst solution. In a 250 ml flask, 10 g of BYK®-307 surfactant obtained from BK-Chemie was added to 90 g of ethanol and stirred for 1 hour at room temperature to prepare a 10 wt. % surfactant solution. In another 250 ml flask, 20.0 g of GR908F resin was added to 80.0 g of PGMEA and stirred for 1 hour at room temperature to form a GR908F resin solution. In another 250 ml flask, 20.0 g of GR150F resin was added to 80.0 g of PGMEA and stirred for 1 hour at room temperature to form a GR150F resin solution. In another 250 ml flask, 60.0 g 20% GR908F solution and 40.0 g 20% GR150F solution were added, then 1.25 g of the 10 wt. % surfactant solution, 0.8 g of the 2 wt. % TMAN catalyst solution, and 0.2 g 3-Glycidoxypropyldimethylethoxysilane SIG5825.0 from Gelest were added to the 100 g of the GR908F/GR150F resin solution was heated to refluxing for 4 hr to form a coating composition. The coating composition was filtered through a 0.45-micron and 0.1-micron filters for coating. The filtered coating composition was coated on a four-inch silicon wafer by spin coating at 1,500 revolutions per minute (RPM). The wafer with the cast film was baked on a first hot plate having a surface temperature of 80° C. for 60 seconds and then baked on a second hot plate having a surface temperature of 160° C. for 120 seconds, to evaporate the solvents. Film thickness of the coating was about 8826 A. Calculated SiOH loss during film curing was 0.026. This formulation shows higher crack-free thickness (8.9 μm) than the GR150F film which has similar Mw but no GR908F or Glycidoxypropyldimethylethoxysilane in the composition.

### Example 38—Pre-Condensed GR150F Poly(silsesquioxane) Resin

In 100 ml flask, 0.5 g of tetramethylammonium nitrate (TMAN) catalyst was added to 24.5 g of deionized water and stirred for 1 hour at room temperature to prepare a 2 wt. % TMAN catalyst solution. In a 250 ml flask, 10 g of BYK®-307 surfactant obtained from BK-Chemie was added to 90 g of ethanol and stirred for 1 hour at room temperature to prepare a 10 wt. % surfactant solution. In another 250 ml flask, 20.8 g of GR150F resin was added to 83.3 g of PGMEA and stirred for 1 hour at room temperature to form a GR150F resin solution. 0.15 g of the 10 wt. % surfactant solution, 0.84 g of the 2 wt. % TMAN catalyst solution were added to the 104.1 g of the resin solution, the solution was heated to refluxing for 150 min, then cooled down to RT, the solution was subject to three pre-condensing steps each for 60 min at refluxing. The coating composition was cooled down to room temperature and filtered through a 0.1-micron filter for coating.

Molecular weight of was measured on Gel permeation chromatography (GPC), Weight average molecular weight (Mw) of the resin was about 50139 Dalton after pre-condensing.

The filtered coating composition was coated on a four-inch silicon wafer by spin coating at 1,500 revolutions per minute (RPM). The wafer with the cast film was baked on a first hot plate having a surface temperature of 80° C. for 60 seconds and then baked on a second hot plate having a surface temperature of 160° C. for 120 seconds, to evaporate the solvents. Film thickness of the coating was about 7910 A. The baked wafer was further cured in a nitrogen ambient at 300° C. for 1 hour. Film thickness was 7860 A.

### Example 39—Pre-Condensed Coating Composition with Silane Monomers

In 250 ml flask, 35.55 g of methyltriethoxy silane (MTEOS), 47.93 g of phenyltriethoxysilane (PTEOS), and 0.18 g of dimethyldiethoxysilane (DMDEOS) were added to 60.0 g of PGMEA, stir for 15 min, then add 18.0 g of 0.008N HNO3, the solution was heated to refluxing for 8 hrs, then added 4.0 g of 5% tetramethylammonium hydroxide aqueous solution, continue heating at refluxing for 8 hrs. 2.26 g of 1N HNO3 was added to the solution after cooling down to RT.

Molecular weight of was measured on Gel permeation chromatography (GPC), Weight average molecular weight (Mw) of the polymer was about 9485 Dalton after pre-condensing.

The filtered coating composition was coated on a four-inch silicon wafer by spin coating at 1,500 revolutions per minute (RPM). The wafer with the cast film was baked on a first hot plate having a surface temperature of 80° C. for 60 seconds and then baked on a second hot plate having a surface temperature of 160° C. for 120 seconds, to evaporate the solvents. Film thickness of the coating was about 12722 A.

### Example 40—Pre-Condensed Coating Composition with Silane Monomers

In 1000 ml flask, 266.65 g of methyltriethoxy silane, 359.47 g of phenyltriethoxysilane, and 1.33 g of dimethyldiethoxysilane were added to 600.0 g of PGMEA, stir for 15 min, then add 135.0 g of 0.008N HNO3, the solution was heated to refluxing for 8 hrs, then added 30.0 g of 5% tetramethylammonium hydroxide aqueous solution, continue heating at refluxing for 11 hrs. 16.95 g of 1N HNO3 was added to the solution after cooling down to RT.

Molecular weight of was measured on Gel permeation chromatography (GPC), Weight average molecular weight (Mw) of the polymer was about 24535 Dalton after pre-condensing.

The filtered coating composition was coated on a four-inch silicon wafer by spin coating at 1,500 revolutions per minute (RPM). The wafer with the cast film was baked on a first hot plate having a surface temperature of 80° C. for 60 seconds and then baked on a second hot plate having a surface temperature of 160° C. for 120 seconds, to evaporate the solvents. Film thickness of the coating was about 13283 A.

TABLE 1
Different polymer coatings & SiOH loss during curing

| | | | Pre-curing | FT | Final | FT | SiOH Loss |
|---|---|---|---|---|---|---|---|
| | | Aryl/Alkyl | thermal | before | curing | after | during |
| Ex | Polymers | Ratio | process | curing (A) | process | curing (A) | curing |
| 1 | GR950F | all aryl | 80 C. × 1 min + | 5621 | 300 C. | 4921 | 0.296 |
| | | | 160 C. × 2 min | | 60 min | | |
| 2 | GR650F | 0 | 80 C. × 1 min + | 6220 | 300 C. | 5006 | 0.248 |
| | | | 160 C. × 2 min | | 60 min | | |
| 3 | GR100F | 0.43 | 80 C. × 1 min + | 6169 | 300 C. | 5467 | 0.134 |
| | | | 160 C. × 2 min | | 60 min | | |
| 4 | GR150F | 0.99 | 80 C. × 1 min + | 6063 | 300 C. | 5948 | 0.139 |
| | | | 160 C. × 2 min | | 60 min | | |
| 5 | 65% GR150F + | 2.06 | 80 C. × 1 min + | 7283 | 300 C. | 7139 | 0.217 |
| | 35% GR950F | | 160 C. × 2 min | | 60 min | | |

TABLE 2A
Polymers pre-condensing with and without MTAS

| | | | | | | Film | | Film | |
|---|---|---|---|---|---|---|---|---|---|
| | | | | | Pre- | thickness | | Thickness | SiOH |
| | | | | | curing | before | | after | Loss |
| | | Cooking | | Aryl/Alkyl | thermal | curing | Curing | curing | during |
| Ex | Polymers | process | Mw | Ratio | process | (A) | process | (A) | curing |
| 4 | GR150F | no Pre- | 3000 | 0.99 | 80 C. × 1 min + | 6063 | 300 C. | 5948 | 0.139 |
| | | condensing | | | 160 C. × 2 min | | 60 min | | |
| 6 | GR150F- | no Pre- | 6009 | 0.99 | 80 C. × 1 min + | 6274 | 300 C. | 5449 | 0.104 |
| | HMW | condensing | | | 160 C. × 2 min | | 60 min | | |
| 7 | Pre- | refluxing | 13510 | 0.99 | 80 C. × 1 min + | 6583 | 300 C. | 6546 | 0.020 |
| | condensed | for | | | 160 C. × 2 min | | 60 min | | |
| | GR150F | 90 min | | | | | | | |
| 8 | Pre- | refluxing | 36271 | 0.99 | 80 C. × 1 min + | 7565 | 300 C. | 7546 | 0.012 |
| | condensed | for | | | 160 C. × 2 min | | 60 min | | |
| | GR150F | 180 min | | | | | | | |
| 9 | Pre- | 2-step | 32070 | 0.99 | 80 C. × 1 min + | 7026 | 300 C. | 7060 | 0.015 |
| | condensed | Refluxing | | | 160 C. × 2 min | | 60 min | | |
| | GR150F | 45 min + | | | | | | | |
| | | 15 min | | | | | | | |
| 10 | GR150F- | refluxing | 5509 | 0.99 | 80 C. × 1 min + | 6298 | 300 C. | 6287 | 0.045 |
| | Pre- | for | | | 160 C. × 2 min | | 60 min | | |
| | condensed | 90 min | | | | | | | |
| | with | | | | | | | | |
| | MTAS | | | | | | | | |

TABLE 2B
Percent SiOH Loss from Pre-Condensing Examples 7-10

| | | % SiOH groups |
|---|---|---|
| | % SiOH removed from | remaining in the |
| Ex | Pre-Condensing | composition |
| 7 | about 86% | about 14% |
| 8 | about 91% | about 9% |
| 9 | about 89% | about 11% |
| 10 | about 68% | about 32% |

TABLE 3
SiOH Loss for GR150F film with different thermal process

| | | | | Film | | Film | |
|---|---|---|---|---|---|---|---|
| | | | | thickness | | thickness | SiOH |
| | | Pre-curing | | before | | after | Losss |
| | | thermal | Aryl/Alkyl | curing | Curing | curing | during |
| Ex | Polymers | process | Ratio | (A) | process | (A) | curing |
| 5 | 65% GR150F + | 80 C. × 1 min + | 2.06 | 7283 | 300 C. | 7139 | 0.217 |
| | 35% GR950F | 160 C. × 2 min | | | 60 min | | |
| 11 | 65% GR150F + | 80 C. × 1 min | 2.06 | 7399 | 300 C. | 7156 | 0.242 |
| | 35% GR950F | | | | 60 min | | |
| 12 | GR150F | 80 C. × 1 min + | 0.99 | 7367 | 300 C. | 7218 | 0.165 |
| | | 160 C. × 1 min | | | 60 min | | |
| 13 | GR150F | 80 C. × 1 min + | 0.99 | 7340 | 300 C. | 7214 | 0.146 |
| | | 160 C. × 2 min | | | 60 min | | |
| 14 | GR150F | 80 C. × 1 min + | 0.99 | 7311 | 300 C. | 7252 | 0.076 |
| | | 160 C. × 5 min | | | 60 min | | |
| 15 | GR150F | 80 C. × 1 min + | 0.99 | 7284 | 300 C. | 7296 | 0.013 |
| | | 160 C. × 10 min | | | 60 min | | |
| 16 | GR150F | 80 C. × 1 min + | 0.99 | 7377 | 300 C. | 7223 | 0.152 |
| | | 180 C. × 1 min | | | 60 min | | |
| 17 | GR150F | 80 C. × 1 min + | 0.99 | 7334 | 300 C. | 7265 | 0.069 |
| | | 180 C. × 2 min | | | 60 min | | |
| 18 | GR150F | 80 C. × 1 min + | 0.99 | 7293 | 300 C. | 7311 | 0.012 |
| | | 180 C. × 5 min | | | 60 min | | |
| 19 | GR150F | 80 C. × 1 min + | 0.99 | 7288 | 300 C. | 7312 | 0.005 |
| | | 180 C. × 10 min | | | 60 min | | |

TABLE 4A
Different polymer coatings & cracking-free thickness

| | Polymers and additives | | | | SiOH | Cracking- |
|---|---|---|---|---|---|---|
| | (% of the additive is | | | | Loss | free |
| | its wt relative to | Aryl/Alkyl | Thermal | FT | during | thickness |
| Ex | the polymer wt) | Ratio | process | (A) | curing | (μm) |
| 20 | GR150F + 3% DPDS | 1.07 | 80 C. × 1 min + | 6739 | N/A | 5.7 |
| | | | 160 C. × 2 min | | | |
| 21 | GR150F + 10% DPDS | 1.28 | 80 C. × 1 min + | 9664 | N/A | 5.4 |
| | | | 160 C. × 2 min | | | |
| 22 | GR150F + 10% MPDS | 1.28 | 80 C. × 1 min + | 9117 | N/A | 5.4 |
| | | | 160 C. × 2 min | | | |
| 23 | GR150F + 3% | 1.07 | 80 C. × 1 min + | 6443 | N/A | 5.7 |
| | DPDS + 1% MPDS | | 160 C. × 2 min | | | |
| 24 | GR150F + 5% | 1.12 | 80 C. × 1 min + | 9015 | N/A | 5.4 |
| | DPDS + 5% MPDS | | 160 C. × 2 min | | | |
| 25 | GR150F + 3% | 1.07 | 80 C. × 1 min + | 7067 | N/A | 5.4 |
| | DPDS + 1% DMDS | | 160 C. × 2 min | | | |
| 26 | GR150F + 1% | 0.99 | 80 C. × 1 min + | 6608 | N/A | 6.8 |
| | Bis(triethoxyl | | 160 C. × 2 min | | | |
| | silyl ethane) | | | | | |
| 27 | GR150F + 0.5% | 0.99 | 80 C. × 1 min + | 7195 | N/A | 6.5 |
| | Bis(triethoxysilyl)benzene | | 160 C. × 2 min | | | |
| 28 | GR150F + 0.5% | 0.99 | 80 C. × 1 min + | 10881 | N/A | 6.5 |
| | Bis(triethoxysilyl)octane | | 160 C. × 2 min | | | |
| 29 | GR150F + 1% | 0.99 | 80 C. × 1 min + | 6730 | N/A | 6.1 |
| | Bis(triethoxysilyl)octane | | 160 C. × 2 min | | | |
| 30 | GR150F + 1% | 0.99 | 80 C. × 1 min + | 14163 | N/A | 4.7 |
| | Glycidyloxypropyltri- | | 160 C. × 2 min | | | |
| | methoxysilane | | | | | |
| 31 | 70% GR908 + 30% GR150F | 2.07 | 80 C. × 1 min + | 7075 | 0.013 | 5.7 |
| | | | 160 C. × 2 min | | | |
| 32 | Cooked 70% GR908 + | 2.07 | 80 C. × 1 min + | 7231 | 0.013 | 7.8 |
| | Cooked 30% GR150F | | 160 C. × 2 min | | | |
| 33 | 70% GR908 + 30% GR150F + | 2.07 | 80 C. × 1 min + | 6910 | 0.013 | 5.6 |
| | A-1170-TFAA | | 160 C. × 2 min | | | |
| 34 | 60% GR908 + 40% GR150F + | 1.85 | 80 C. × 1 min + | 7097 | 0.018 | 5.6 |
| | A-1170-TFAA | | 160 C. × 2 min | | | |
| 35 | 60% GR908 + 40% GR150F + | 1.85 | 80 C. × 1 min + | 9697 | 0.014 | 10.3 |
| | 5% MPDS + 5% DPDS | | 160 C. × 2 min | | | |
| 36 | 60% GR908 + 40% GR150F + | 1.85 | 80 C. × 1 min + | 8012 | 0.034 | 8.3 |
| | 1% Bis(triethoxysilyl)benzene | | 160 C. × 2 min | | | |
| 37 | 60% GR908 + 40% GR150F + 1% | 1.85 | 80 C. × 1 min + | 8826 | 0.026 | 8.9 |
| | Glycidoxypropyldi- | | 160 C. × 2 min | | | |
| | methylethoxysilane | | | | | |
| 39 | MTEOS + PTEOS + DMDEOS | 0.99 | 80 C. × 1 min + | 12722 | 0.036 | N/A |
| | | | 160 C. × 2 min | | | |
| 40 | MTEOS + PTEOS + DMDEOS | 0.99 | 80 C. × 1 min + | 13283 | 0.015 | N/A |
| | | | 160 C. × 2 min | | | |

TABLE 4B
Percent SiOH Removed from Pre-Condensing Examples 31-40

| | % SiOH removed from | % SiOH remaining in |
|---|---|---|
| Ex | Pre-Condensing | the composition |
| 31 | about 91% | about 9% |
| 32 | about 91% | about 9% |
| 33 | about 91% | about 9% |
| 34 | about 87% | about 13% |
| 35 | about 90% | about 10% |
| 36 | about 76% | about 24% |
| 37 | about 81% | about 18% |
| 38 | about 74% | about 26% |
| 39 | about 89% | about 11% |
| 40 | about 91% | about 9% |

### II. Moisture Evolution Measurements

Moisture content in the sample was measured using indirect coulometric Karl Fischer (KF) titration with a KF oven, utilizing the ECH-Aqua 40.00 with a Head Space VARIO module and an autosampler. The titration was performed in a coulometric titration cell with a generator electrode without a diaphragm. A sample size of 0.65 g was used, with the KF-oven temperature gradient set from 50-300° C. at a rate of 1° C./min, followed by isothermal heating at 300° C. for 40 minutes. Dried air, passed through molecular sieves (3 A), was used as the carrier gas to ensure dryness. Moisture outgassing from 50˜75 C was mainly free water from the solutions, condensation moisture was observed after 75 C, the moisture content of the polymers is defined as the difference between the total moisture outgassing and the moisture outgassing from 50˜75 C.

TABLE 5
Different polymer coatings & moisture contents

| | | | | | | | | | Total | |
|---|---|---|---|---|---|---|---|---|---|---|
| | | | | | | | | Moisture | moisture | Moisture |
| | | | | Pre- | FT | | FT | in | in | content |
| | | Pre- | | curing | before | | after | solution | solution | in |
| | | condensing | | thermal | curing | Curing | curing | (50~75 C.) | (50~300 | polymer |
| Ex | Polymers | process | Mw | process | (A) | process | (A) | (ppm) | C.) (ppm) | (ppm) |
| 4 | GR150F | no pre- | 3000 | 80 C. × 1 min + | 6063 | 300 C. | 5948 | 6770 | 11610 | 4840 |
| | | condensing | | 160 C. × 2 min | | 60 min | | | | |
| 9 | Pre- | 2-step | 32070 | 80 C. × 1 min + | 7026 | 300 C. | 7060 | 12230 | 14080 | 1850 |
| | condensed | Refluxing | | 160 C. × 2 min | | 60 min | | | | |
| | GR150F | 45 min + | | | | | | | | |
| | | 15 min | | | | | | | | |
| 38 | Pre- | 4-step | 50139 | 80 C. × 1 min + | 7910 | 300 C. | 7860 | 11230 | 12390 | 1160 |
| | condensed | Refluxing | | 160 C. × 2 min | | 60 min | | | | |
| | GR150F | 150 min + | | | | | | | | |
| | | 60 min + 60 | | | | | | | | |
| | | min + 60 min | | | | | | | | |

As shown in FIG. 3, a graph of the moisture evolution of examples 4, 9, and 38 are shown. Example 4 did not undergo a pre-condensing step, while examples 9 and 38 underwent pre-condensing. Between temperatures of about 50° C. to about 100° C., the graph shows free moisture evolution prior to final cure for each example. Then, the examples were heated above about 100° C. to about 300° C. for final cure. The slopes of the graphs during final cure temperatures depicts the amount of condensing moisture evolution during final cure.

Example 4 showed little free moisture evolution prior to final cure. Moisture evolution between about 50° C. to about 100° C. for Example 4 was mostly due to free water evaporation. There is a steep incline as the example is heated to final cure, signifying a significant amount of condensing moisture evolving during final cure.

Conversely, the pre-condensed examples (9 and 38) had much more free moisture removed in the period prior to final cure. Then, as the examples were heated to final cure temperatures, the slope of the graphs is gradual and more shallow than the slope of example 4. This shows that only a small amount of condensing moisture is evolved during final cure of examples 9 and 38.

The results of FIG. 3 show that coating compositions that are pre-condensed have more free moisture evolution prior to final cure and less condensing moisture evolution during final cure than coating compositions that are not pre-condensed. As discussed above, it is preferable to remove a maximum amount of condensing moisture from the coating composition prior to final cure and reduce the amount of condensing moisture removed during final cure to minimize damage to moisture sensitive layers.

### ASPECTS

Aspect 1 is a method of forming a coating composition for planarizing the surface of a semiconductor device, comprising: combining silicon-containing compounds selected from one or more of silanes, polysiloxanes, poly(silsesquioxanes), and combinations of the foregoing to form a composition, the silicon-containing compounds having a first, initial silanol group (SiOH) content following combining; and pre-condensing the composition to reduce the first, initial silanol group (SiOH) to a second, reduced silanol group (SiOH) content.

Aspect 2 is the method of Aspect 1, wherein the composition further comprises at least one of a catalyst and a solvent.

Aspect 3 is the method of Aspect 1 or Aspect 2, wherein the pre-condensing comprises heating the composition to a temperature above room temperature.

Aspect 4 is the method of any one of Aspects 1-3, wherein pre-condensing further comprises heating the composition to a temperature from about 50° C. to about 250° C.

Aspect 5 is the method of Aspect 3 or Aspect 4, wherein the composition is heated for at least 10 seconds.

Aspect 6 is the method of any one of Aspects 1-5, wherein pre-condensing reduces an amount of SiOH groups by 30% to 95%, based on the total number of SiOH groups in the composition before heating.

Aspect 7 is the method of any one of Aspects 1-6, wherein the catalyst is selected from inorganic and organic acids and inorganic and organic bases.

Aspect 8 is the method of any one of Aspects 1-7, wherein the composition further comprises a water scavenger comprising a silane with methoxy groups, acetoxy groups, or a combination thereof.

Aspect 9 is the method of any one of Aspects 1-8, wherein the composition comprises a poly(silsesquioxane) selected from: a poly(silsesquioxane) comprising poly(phenylsilsesquioxane) blocks and poly(methylsilsesquioxane) blocks; a poly(silsesquioxane) comprising consisting essentially of poly(phenylsilsesquioxane) blocks; a poly(silsesquioxane) comprising consisting essentially of poly(methylsilsesquioxane) blocks; and combinations of the foregoing.

Aspect 10 is the method of any one of Aspects 1-9, wherein the composition has a ratio of aryl/alkyl groups from 0.9 to 10, based on the total mol % of all alkyl and aryl groups in all of the silicon-containing compounds.

Aspect 11 is a method of planarizing a surface of a semiconductor device, comprising: applying, to a surface of a semiconductor device, a composition comprising the reaction product of one or more of silanes, polysiloxanes, poly(silsesquioxanes), and combinations of the foregoing, the composition having a first, initial silanol group (SiOH) content; and curing the composition to provide a second, reduced silanol group (SiOH) content with a silanol group (SiOH) loss of less than 0.3.

Aspect 12 is the method of Aspect 11, wherein the reaction product is the reaction product of at least one poly(silsesquioxane) selected from: a poly(silsesquioxane) comprising poly(phenylsilsesquioxane) blocks and poly(methylsilsesquioxane) blocks; a poly(silsesquioxane) comprising consisting essentially of poly(phenylsilsesquioxane) blocks; a poly(silsesquioxane) comprising consisting essentially of poly(methylsilsesquioxane) blocks; and combinations of the foregoing.

Aspect 13 is the method of Aspect 11 or Aspect 12, wherein the curing step is conducted at 300° C. for 1 hour.

Aspect 14 is the method of any one of Aspects 11-13, wherein the semiconductor device comprises at least one moisture sensitive layer selected from at least one of an Indium Gallium Zinc Oxide (IGZO) layer and a Low Temperature Polycrystal Silicon (LTPS) layer.

Aspect 15 is the method of any one of Aspects 11-14, wherein silanol group (SiOH) loss is less than 0.1.

Aspect 16 is a composition for planarizing the surface of a semiconductor device, comprising: the reaction product of one or more of silicone monomers, polysiloxanes, poly(silsesquioxanes), and combinations of the foregoing and having a first, initial silanol group (SiOH) content, the reaction product capable, upon application to a surface of a semiconductor device and curing, of providing a second, reduced silanol group (SiOH) with a silanol group (SiOH) loss of less than 0.3.

Aspect 17 is the composition of Aspect 16, wherein the reaction product is the reaction product of at least one poly(silsesquioxane) selected from: a poly(silsesquioxane) comprising poly(phenylsilsesquioxane) blocks and poly(methylsilsesquioxane) blocks; a poly(silsesquioxane) comprising consisting essentially of poly(phenylsilsesquioxane) blocks; a poly(silsesquioxane) comprising consisting essentially of poly(methylsilsesquioxane) blocks; and combinations of the foregoing.

Aspect 18 is the composition of Aspect 16 or Aspect 17, further comprising a solvent selected from aromatic hydrocarbons, aliphatic hydrocarbons, halogenated hydrocarbons, esters, ketones, and mixtures of the foregoing.

Aspect 19 is the composition of any one of Aspects 16-18, further comprising a ratio of aryl/alkyl groups from 0.9 to 10, based on the total mol % of all alkyl and aryl groups in all of the silicon-containing compounds.

Aspect 20 is the composition of any one of Aspects 16-19, wherein the reaction product of either one or more polysiloxane and one or more poly(silsesquioxanes) or one or more silicone monomers and one or more poly(silsesquioxanes).

Aspect 21 is the coating composition of any one of claims 16-20, wherein the coating composition has a crack-free thickness from 1 μm to 20 μm.

Aspect 22 is an article coating with a coating composition, wherein at least one of: the coating composition is according to any one of Aspects 16-21; and the article is coated according to the method of any one of Aspects 1-15.

Aspect 23 is an article coated with a coating composition, the coating composition comprising: the reaction product of one or more of silicone monomers, polysiloxanes, poly(silsesquioxanes), and combinations of the foregoing and having a first, initial silanol group (SiOH) content, the reaction product capable, upon application to a surface of a semiconductor device and curing, of providing a second, reduced silanol group (SiOH) with a silanol group (SiOH) loss of less than 0.3.

Aspect 24 is the article of Aspect 23, wherein the reaction product is the reaction product of at least one poly(silsesquioxane) selected from: a poly(silsesquioxane) comprising poly(phenylsilsesquioxane) blocks and poly(methylsilsesquioxane) blocks; a poly(silsesquioxane) comprising consisting essentially of poly(phenylsilsesquioxane) blocks; a poly(silsesquioxane) comprising consisting essentially of poly(methylsilsesquioxane) blocks; and combinations of the foregoing.

Aspect 25 is the article of Aspect 23 or Aspect 24, further comprising a solvent selected from aromatic hydrocarbons, aliphatic hydrocarbons, halogenated hydrocarbons, esters, ketones, and mixtures of the foregoing.

Aspect 26 is the article of any one of Aspects 23-25, further comprising a ratio of aryl/alkyl groups from 0.9 to 10, based on the total mol % of all alkyl and aryl groups in all of the silicon-containing compounds.

Aspect 27 is the article of any one of Aspects 23-26, wherein the reaction product of either one or more polysiloxane and one or more poly(silsesquioxanes) or one or more silicone monomers and one or more poly(silsesquioxanes).

Aspect 28 is the article of any one of Aspects 23-27, wherein the coating composition has a crack-free thickness from 1 μm to 20 μm.

Aspect 29 is an article coated with a coating composition, wherein the article is coated according to a method comprising: combining silicon-containing compounds selected from one or more of silanes, polysiloxanes, poly(silsesquioxanes), and combinations of the foregoing to form a composition, the silicon-containing compounds having a first, initial silanol group (SiOH) content following combining; pre-condensing the composition; curing the composition.

Aspect 30 is the article of Aspect 29, wherein pre-condensing comprises heating the composition to a temperature above room temperature.

Aspect 31 is the article of either Aspect 29 or Aspect 30, wherein pre-condensing comprises heating the composition to a temperature from about 50° C. to about 250° C.

Aspect 32 is the article of any one of Aspect 29-31, wherein pre-condensing lasts for at least 10 seconds.

Aspect 33 is the article of any one of Aspects 29-32, wherein pre-condensing reduces the amount of SiOH groups by 30% to 95%, based on the total number of SiOH groups in the composition before heating.

Aspect 34 is the article of any one of Aspect 29-33, wherein curing comprises heating the composition to a temperature above 300° C.

Aspect 35 is the article of any one of Aspects 29-34, wherein the composition has a ratio of aryl/alkyl groups from 0.9 to 10, based on the total mol % of all alkyl and aryl groups in all of the silicon-containing compounds.

Aspect 36 is the method of any one of Aspects 15 or the article of any one of Aspects 29-35, wherein the silicon containing compound comprises a difunctional siloxane according to the formula:

R₂Si(OR′)₂
wherein:
   R is one or more moieties chosen independently from linear, branched, or cyclic alkyl and aryl; and
   R′ is methyl, ethyl, propyl or alkyl.

Aspect 37 is the method of any one of Aspects 15 or the article of any one of Aspects 29-35, wherein the silicon containing compound comprises a bipodal silicone monomer according to the formula:

(OR¹)₃Si—R²—Si(OR³)₃
wherein:
   R¹ is methyl, ethyl, propyl, or alkyl;
   R² is an organic group comprising aliphatic and/or aromatic hydrocarbons; and
   R³ is methyl, ethyl, propyl, or alkyl.

Aspect 38 is the method of any one of Aspects 15 or the article of any one of Aspects 29-35, wherein the silicon containing compound comprises a silicone monomer according to the formula:

RₓSi(OR′)₄₋ₓ
wherein:
   R is one or more moieties chosen independently from linear, branched, or cyclic alkyl and aryl;
   R′ is methyl, ethyl, propyl or alkyl; and
   x is at least 0 and less than 4, including any of 0, 1, 2 and 3.

What is claimed is:

1. A method of forming a coating composition for planarizing the surface of a semiconductor device, comprising:
combining silicon-containing compounds selected from one or more of silanes, polysiloxanes, poly(silsesquioxanes), and combinations of the foregoing to form a composition, the silicon-containing compounds having a first, initial silanol group (SiOH) content following combining; and
pre-condensing the composition.

2. The method of claim 1, wherein the composition further comprises at least one of a catalyst and a solvent.

3. The method of claim 1, wherein the pre-condensing comprises heating the composition to a temperature above room temperature.

4. The method of claim 1, wherein pre-condensing further comprises heating the composition to a temperature from about 50° C. to about 250° C.

5. The method of claim 1, wherein pre-condensing reduces an amount of SiOH groups by 30% to 95%, based on the total number of SiOH groups in the composition before heating.

6. The method of claim 1, wherein the composition comprises a poly(silsesquioxane) selected from:
a poly(silsesquioxane) comprising poly(phenylsilsesquioxane) blocks and poly(methylsilsesquioxane) blocks;
a poly(silsesquioxane) comprising consisting essentially of poly(phenylsilsesquioxane) blocks;
a poly(silsesquioxane) comprising consisting essentially of poly(methylsilsesquioxane) blocks; and
combinations of the foregoing.

7. The method of claim 1, wherein the composition has a ratio of aryl/alkyl groups from 0.9 to 10, based on the total mol % of all alkyl and aryl groups in all of the silicon-containing compounds.

8. The method of claim 1, wherein the one or more of silanes, polysiloxanes, poly(silsesquioxanes), and combinations of the foregoing comprises one or more polysiloxane and one or more poly(silsesquioxanes); or one or more silicone monomers and one or more poly(silsesquioxanes).

9. An article coated with a coating composition according to the method of claim 1.

10. A method of planarizing a surface of a semiconductor device, comprising:
applying, to a surface of a semiconductor device, a composition comprising the reaction product of one or more of silanes, polysiloxanes, poly(silsesquioxanes), and combinations of the foregoing, the composition having a first, initial silanol group (SiOH) content; and
curing the composition to provide a second, reduced silanol group (SiOH) content with a silanol group (SiOH) loss of less than 0.3.

11. The method of claim 10, wherein the reaction product is the reaction product of at least one poly(silsesquioxane) selected from:
a poly(silsesquioxane) comprising poly(phenylsilsesquioxane) blocks and poly(methylsilsesquioxane) blocks;
a poly(silsesquioxane) comprising consisting essentially of poly(phenylsilsesquioxane) blocks;
a poly(silsesquioxane) comprising consisting essentially of poly(methylsilsesquioxane) blocks; and
combinations of the foregoing.

12. The method of claim 10, wherein the semiconductor device comprises at least one moisture sensitive layer selected from at least one of an Indium Gallium Zinc Oxide (IGZO) layer and a Low Temperature Polycrystal Silicon (LTPS) layer.

13. The method of claim 10, wherein silanol group (SiOH) loss is less than 0.1.

14. An article coated with a coating composition according to the method of claim 10.

15. A composition for planarizing the surface of a semiconductor device, comprising:
the reaction product of one or more of silicone monomers, polysiloxanes, poly(silsesquioxanes), and combinations of the foregoing and having a first, initial silanol group (SiOH) content, the reaction product capable, upon application to a surface of a semiconductor device and curing, of providing a second, reduced silanol group (SiOH) with a silanol group (SiOH) loss of less than 0.3.

16. The composition of claim 15, wherein the reaction product is the reaction product of at least one poly(silsesquioxane) selected from:
a poly(silsesquioxane) comprising poly(phenylsilsesquioxane) blocks and poly(methylsilsesquioxane) blocks;
a poly(silsesquioxane) comprising consisting essentially of poly(phenylsilsesquioxane) blocks;
a poly(silsesquioxane) comprising consisting essentially of poly(methylsilsesquioxane) blocks; and
combinations of the foregoing.

17. The composition of claim 15, further comprising a solvent selected from aromatic hydrocarbons, aliphatic hydrocarbons, halogenated hydrocarbons, esters, ketones, and mixtures of the foregoing.

18. The composition of claim 15, further comprising a ratio of aryl/alkyl groups from 0.9 to 10, based on the total mol % of all alkyl and aryl groups in all of the silicon-containing compounds.

19. The composition of claim 15, wherein the reaction product of either one or more polysiloxane and one or more poly(silsesquioxanes) or one or more silicone monomers and one or more poly(silsesquioxanes).

20. An article coated with a coating composition of claim 15.
